(19) United States
(12) Patent Application Publication
(10) Pub. No.: US 2018/0145124 A1
(43) Pub. Date: May 24, 2018

(54) FLEXIBLE DISPLAY DEVICE

(71) Applicant: Samsung Display Co., Ltd., Yongin-si (KR)

(72) Inventors: Youngbin KIM, Cheonan-si (KR); Mugyeom KIM, Hwaseong-si (KR)

(21) Appl. No.: 15/356,663

(22) Filed: Nov. 21, 2016

(51) Int. Cl. H01L 27/32; H01L 51/52; H01L 29/45; H01L 51/56; H01L 51/00

(52) U.S. Cl. CPC H01L 27/3276; H01L 27/3262; H01L 27/3258; H01L 27/3248; H01L 51/5218; H01L 27/1218; H01L 51/5237; H01L 51/56; H01L 51/003; H01L 2251/5338; H01L 2251/558; H01L 29/45

(57) ABSTRACT

An apparatus includes a flexible substrate, an electrode, and a signal line. The flexible substrate includes a first area extending along a plane, and a second area extending from the first area. The second area is bent away from the plane. The electrode overlaps the first area. The signal line is disposed in association with the first area and the second area. The signal line is electrically connected to the electrode. A neutral plane of the second area extends in the signal line.

### BACKGROUND

### Field

Exemplary embodiments relate to display technology, and, more particularly, to flexible display devices.

### Discussion

Display devices have become iconographies of modern information consuming societies. Whether in the form of a cellular phone, consumer appliance, portable computer, television, or the like, aesthetic and ergonomic appeal are as much design considerations as display quality and overall performance. As such, greater attention is being directed towards developing display devices with minimal to no bezel configurations. Flexible display devices capable of permanent deformation (e.g., bending) in areas outlying a display area, and, thereby, capable of reducing the planar surface area of these outlying areas, are gaining traction at least because such configurations also enable peripheral circuitry to remain proximate to the display area. It is noted, however, that as the bend radius of an outlying area decreases, an increasing amount of stress is applied to the bending area. This increase in stress may increase resistivity in and reduce reliability of signal lines extending between the display area and peripheral circuitry configured to drive pixels of the display area. A need, therefore, exists for efficient, cost-effective techniques enabling flexible display devices to be permanently deformed at relatively small bend radii, but maintain sufficient levels of performance and reliability.

The above information disclosed in this Background section is only for enhancement of understanding of the background of the inventive concept, and, therefore, it may contain information that does not form the prior art that is already known to a person of ordinary skill in the art.

### SUMMARY

One or more exemplary embodiments provide apparatuses capable of permanent, reliable deformation of second areas outlying first areas.

Additional aspects will be set forth in the detailed description which follows, and, in part, will be apparent from the disclosure, or may be learned by practice of the inventive concept.

According to one or more exemplary embodiments, an apparatus includes a flexible substrate, an electrode, and a signal line. The flexible substrate includes a first area extending along a plane, and a second area extending from the first area. The second area is bent away from the plane. The electrode overlaps the first area. The signal line is disposed in association with the first area and the second area. The signal line is electrically connected to the electrode. A neutral plane of the second area extends in the signal line.

According to one or more exemplary embodiments, an apparatus includes a flexible substrate, a thin film transistor, and a signal line. The flexible substrate includes a first area extending along a plane and a second area extending from the first area. The second area is bent away from the plane. The thin film transistor overlaps the first area. The signal line is disposed in association with the first area and the second area. The signal line is electrically connected to the thin film transistor. In association with the second area, the signal line is disposed between a first inorganic layer and a second inorganic layer. In association with the first area, the second inorganic layer is disposed between an electrode of the thin film transistor and the first inorganic layer.

According to one or more exemplary embodiments, an apparatus includes a flexible substrate and an electrode disposed on a plane of a first portion of the flexible substrate. A second portion of the flexible substrate is bent away from the plane. A signal line is embedded in the flexible substrate between a pair of inorganic layers of the flexible substrate. The signal line is electrically connected to the electrode. The signal line extends from the second portion into the first portion.

The foregoing general description and the following detailed description are exemplary and explanatory and are intended to provide further explanation of the claimed subject matter.

### BRIEF DESCRIPTION OF THE DRAWINGS

The accompanying drawings, which are included to provide a further understanding of the inventive concept, and are incorporated in and constitute a part of this specification, illustrate exemplary embodiments of the inventive concept, and, together with the description, serve to explain principles of the inventive concept.

FIG. 1 is an exploded perspective view of a display device, according to one or more exemplary embodiments.

FIG. 2A is a perspective view of a flexible display panel of the display device of FIG. 1 in a non-bent state, according to one or more exemplary embodiments.

FIG. 2B is a perspective view of the flexible display panel of FIG. 2A in a bent state, according to one or more exemplary embodiments.

FIG. 3A is a cross-sectional view of the flexible display panel of FIG. 2A taken along sectional line III-III′ in a non-bent state, according to one or more exemplary embodiments.

FIG. 3B is a cross-sectional view of the flexible display panel of FIG. 2A taken along sectional line III-III′ in a bent state, according to one or more exemplary embodiments.

FIG. 4 is a partial cross-sectional view of an assembled state of the display device of FIG. 1, according to one or more exemplary embodiments.

FIG. 5 is an equivalent circuit diagram of a pixel of the flexible display panel of FIGS. 2A and 2B, according to one or more exemplary embodiments.

FIG. 6A is an enlarged view of portion A of the flexible display panel of FIG. 3A, according to one or more exemplary embodiments.

FIGS. 6B and 6C are enlarged views of portion B of a flexible substrate of the flexible display panel of FIG. 6A, according to one or more exemplary embodiments.

FIG. 7 is a flowchart of a process for forming a flexible display panel with at least one bending portion, according to one or more exemplary embodiments.

FIG. 8 is an enlarged view of portion C in a bending portion of the flexible display panel of FIG. 3A, according to one or more exemplary embodiments.

FIG. 9 is a partial cross-sectional view of the bending portion of the flexible display panel of FIGS. 3B and 8, according to one or more exemplary embodiments.

FIG. 10 schematically illustrates a neutral plane of the bending portion of the flexible display panel of FIGS. 8 and 9, according to one or more exemplary embodiments.

FIG. 11 is an enlarged view of portion C in a bending portion of the flexible display panel of FIG. 3A, according to one or more exemplary embodiments.

FIG. 12 schematically illustrates a neutral plane of the bending portion of the flexible display panel of FIG. 11, according to one or more exemplary embodiments.

FIG. 13 is an enlarged view of portion C in a bending portion of the flexible display panel of FIG. 3A, according to one or more exemplary embodiments.

FIG. 14 is partial cross-sectional view of a bending portion of the flexible display panel of FIGS. 3B and 13, according to one or more exemplary embodiments.

FIG. 15 schematically illustrates a neutral plane of the bending portion of the flexible display panel of FIGS. 13 and 14, according to one or more exemplary embodiments.

FIGS. 16 and 17 schematically illustrate a process of depositing organic material on surfaces of a flexible substrate in a bending portion of a flexible display device, according to one or more exemplary embodiments.

FIG. 18 schematically illustrates a process of curing the deposited organic material of FIG. 17, according to one or more exemplary embodiments.

FIG. 19 is a perspective view of a curing apparatus, according to one or more exemplary embodiments.

### DETAILED DESCRIPTION OF THE ILLUSTRATED EMBODIMENTS

In the following description, for the purposes of explanation, numerous specific details are set forth in order to provide a thorough understanding of various exemplary embodiments. It is apparent, however, that various exemplary embodiments may be practiced without these specific details or with one or more equivalent arrangements. In other instances, well-known structures and devices are shown in block diagram form in order to avoid unnecessarily obscuring various exemplary embodiments.

Unless otherwise specified, the illustrated exemplary embodiments are to be understood as providing exemplary features of varying detail of various exemplary embodiments. Therefore, unless otherwise specified, the features, components, modules, layers, films, panels, regions, and/or aspects of the various illustrations may be otherwise combined, separated, interchanged, and/or rearranged without departing from the disclosed exemplary embodiments. Further, in the accompanying figures, the size and relative sizes of layers, films, panels, regions, etc., may be exaggerated for clarity and descriptive purposes. When an exemplary embodiment may be implemented differently, a specific process order may be performed differently from the described order. For example, two consecutively described processes may be performed substantially at the same time or performed in an order opposite to the described order. Also, like reference numerals denote like elements.

When an element or layer is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. Further, the D1-axis, the D2-axis, and the D3-axis are not limited to three axes of a rectangular coordinate system, and may be interpreted in a broader sense. For example, the D1-axis, the D2-axis, and the D3-axis may be perpendicular to one another, or may represent different directions that are not perpendicular to one another. For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, and ZZ. As used herein, the term “and/or” includes any and all combinations of one or more of the associated listed items.

Although the terms “first,” “second,” etc. may be used herein to describe various elements, components, regions, layers, and/or sections, these elements, components, regions, layers, and/or sections should not be limited by these terms. These terms are used to distinguish one element, component, region, layer, and/or section from another element, component, region, layer, and/or section. Thus, a first element, component, region, layer, and/or section discussed below could be termed a second element, component, region, layer, and/or section without departing from the teachings of the present disclosure.

Spatially relative terms, such as “beneath,” “below,” “lower,” “above,” “upper,” “overlapping,” and the like, may be used herein for descriptive purposes, and, thereby, to describe one element or feature's relationship to another element(s) or feature(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof.

Various exemplary embodiments are described herein with reference to sectional illustrations that are schematic illustrations of idealized exemplary embodiments and/or intermediate structures. As such, variations from the shapes of the illustrations as a result, for example, of manufacturing techniques and/or tolerances, are to be expected. Thus, exemplary embodiments disclosed herein should not be construed as limited to the particular illustrated shapes of regions, but are to include deviations in shapes that result from, for instance, manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the drawings are schematic in nature and their shapes are not intended to illustrate the actual shape of a region of a device and are not intended to be limiting.

Unless otherwise defined, all terms (including technical and scientific terms) used herein have the same meaning as commonly understood by one of ordinary skill in the art to which this disclosure is a part. Terms, such as those defined in commonly used dictionaries, should be interpreted as having a meaning that is consistent with their meaning in the context of the relevant art and will not be interpreted in an idealized or overly formal sense, unless expressly so defined herein.

According to one or more exemplary embodiments, a flexible display device refers to a display device having various degrees of flexibility, and may have the same meaning as a bendable display device, a rollable display device, a foldable display device, a twistable display device, and the like.

Although various exemplary embodiments are described with respect to flexible organic light emitting display devices, it is contemplated that various exemplary embodiments are also applicable to other flexible display devices, such as flexible liquid crystal display devices, flexible inorganic electroluminescent display devices, flexible field emission display devices, flexible plasma display devices, flexible electrophoretic display devices, flexible electrowetting display devices, and the like. Further, although various exemplary embodiments are described with respect to flexible display panels incorporated as part of a mobile phone, exemplary embodiments are also applicable to other electronic devices incorporating a flexible display panel, such as televisions, media players, notebook computers, gaming devices, tablets, monitors, navigational aids, pendant devices, billboards, wrist watches, headphones, earpiece devices, consumer appliances, etc. It is also contemplated that exemplary embodiments are applicable to configuring other flexible devices, such as configuring flexible light receiving components of, for instance, photovoltaic cells, configuring flexible touch screen devices, etc.

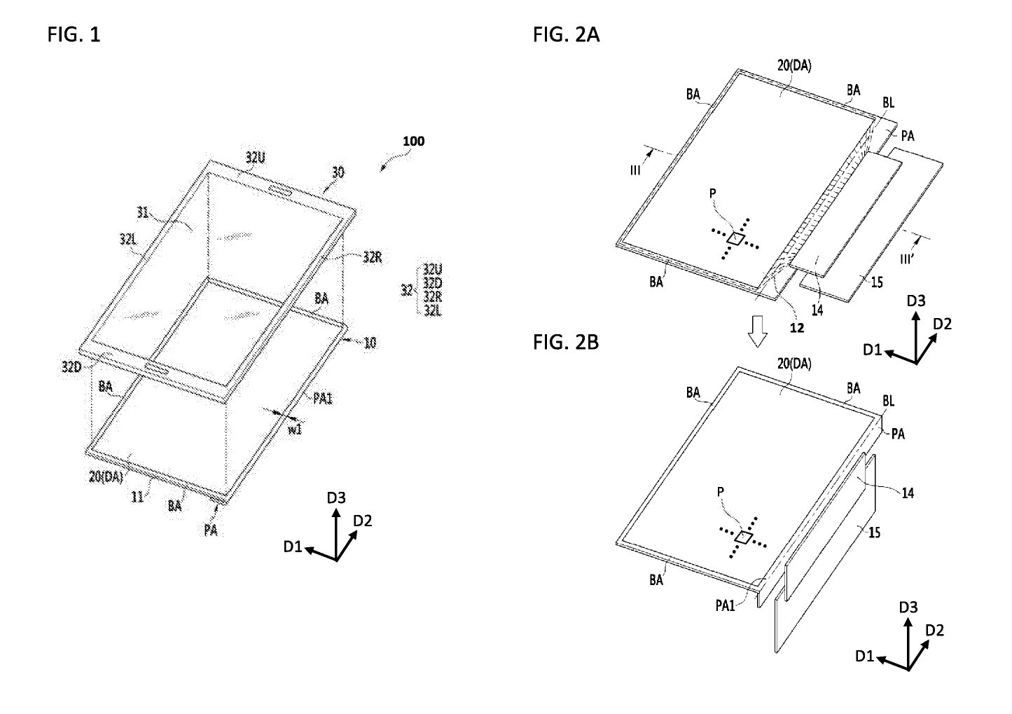

FIG. 1 is an exploded perspective view of a display device, according to one or more exemplary embodiments. FIGS. 2A and 2B are perspective views of a flexible display panel of the display device of FIG. 1, according to one or more exemplary embodiments. That is, FIG. 2A is a perspective view of flexible display panel 10 in a non-bent state, and FIG. 2B is a perspective view of flexible display panel 10 in a first bent state.

Referring to FIGS. 1, 2A, and 2B, display device 100 includes flexible display panel 10 and cover window 30 disposed on flexible display panel 10. Cover window 30 covers, and, thereby, protects flexible display panel 10 from (or reduces the extent of) external impacts, scratches, contaminants, etc. Flexible display panel 10 may be coupled to cover window 30 via, for instance, a transparent adhesive layer (not shown). It is contemplated, however, that any other suitable coupling mechanism may be utilized, such as, chemical bonding, mechanical fasteners, etc. Cover window 30 may be formed directly on a surface of flexible display panel 10. Although not illustrated, display device 100 may include a touch screen, a polarizer, and/or an anti-reflection film. The touch screen, polarizer, and/or anti-reflection film may be disposed between flexible display panel 10 and window 30. It is also contemplated that the touch screen, polarizer, and/or anti-reflection film may be incorporated as a portion, e.g., one or more layers, of flexible display panel 10 and/or window 30.

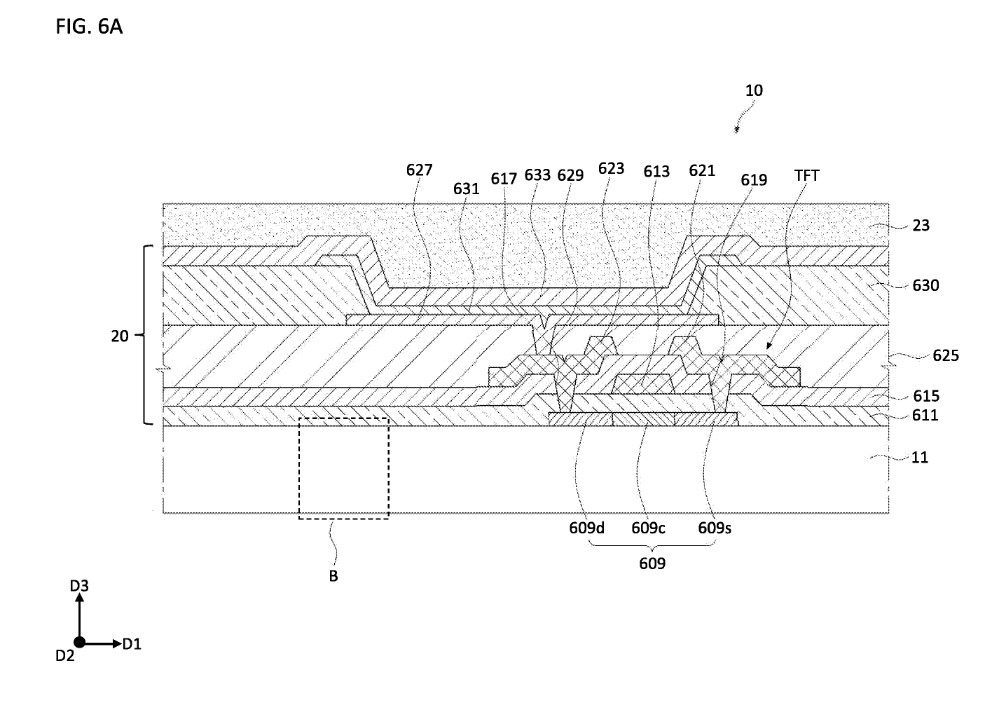

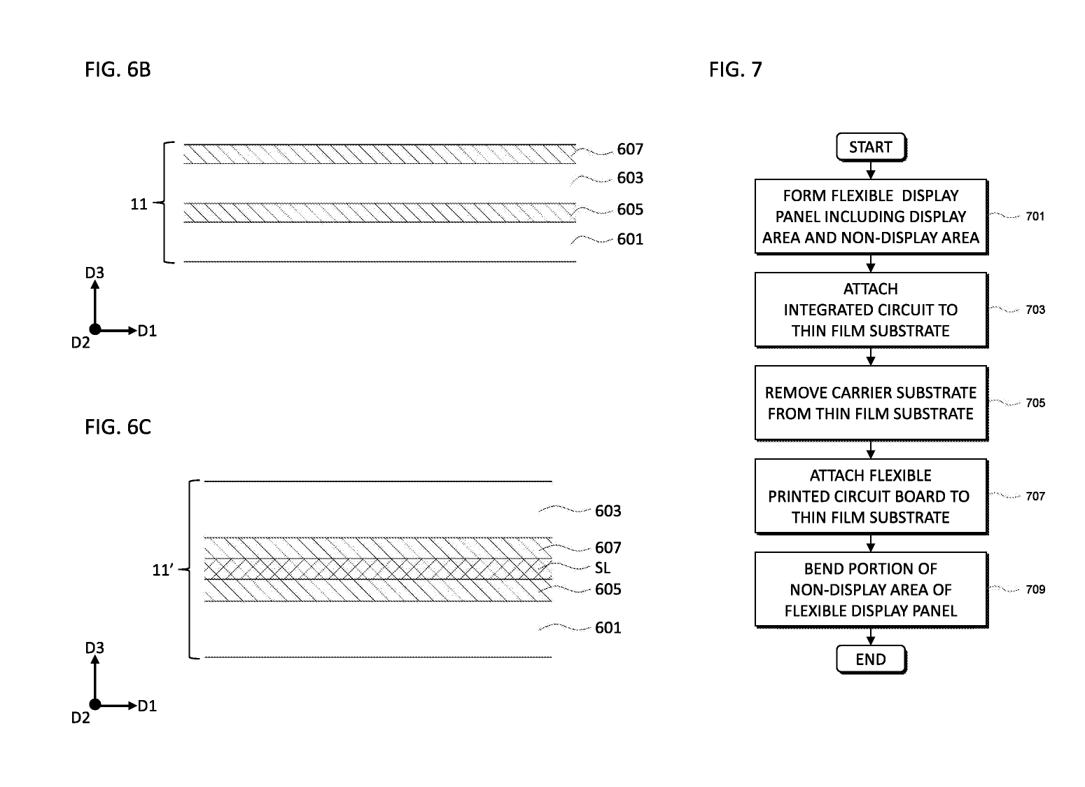

According to one or more exemplary embodiments, flexible display panel 10 is a deformable (e.g., bendable, foldable, flexible, etc.) display panel including flexible substrate 11 on which display structure 20 is formed. Display structure 20 is configured to display an image by combining light from pixels (e.g., pixel P) included as part of display structure 20. Pixels P may be arranged in any suitable formation, such as a matrix formation. As will become more apparent below, flexible substrate 11 may be formed of one or more layers, which may increase the manufacturing yield of flexible display panel 10. To this end, flexible substrate 11 may include one or more organic layers formed of, for instance, a polymer film, such as polyimide, polyethylene naphthalate, polycarbonate, etc. Flexible substrate 11 may also include one or more inorganic layers formed of, for example, amorphous silicon, silicon oxide, silicon nitride, silicon oxynitride, etc. Any other suitable organic and/or inorganic material may be utilized in association with exemplary embodiments. Exemplary flexible substrates 11 are described in more detail in association with FIGS. 6B and 6C.

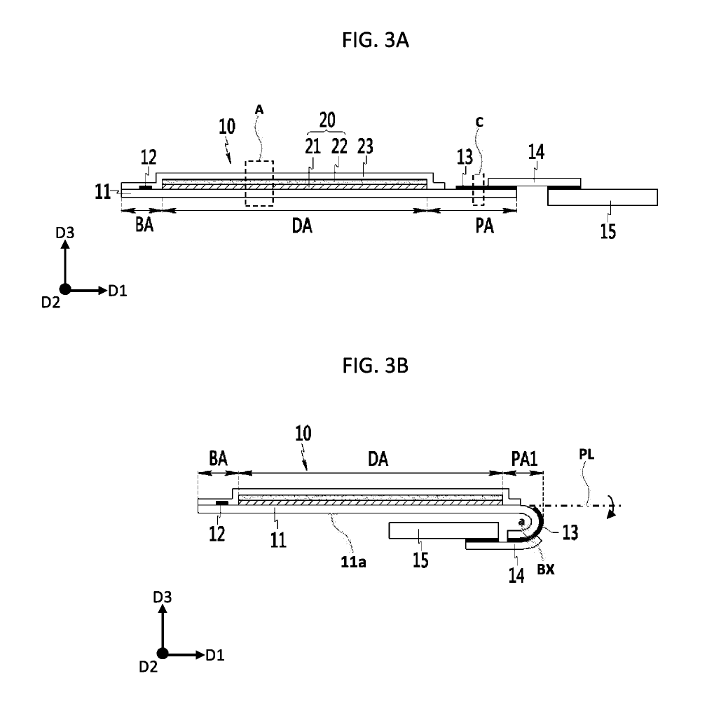

Although not illustrated, pixels P of display structure 20 may be driven, at least in part, via a main driver, a gate driver, a data driver, and a power source. At least one of the main driver, the gate driver, the data driver, and the power source may be coupled to (or integrated as part of) printed circuit board 15. In this manner, signal lines 12 connecting pixels P to the main driver, the gate driver, the data driver, or the power source may pass through pad area PA and extend into display area DA. As such, pixels P may display an image based on signals received via the main driver, the gate driver, the data driver, and the power source. An equivalent circuit of a representative pixel is described in more detail in association with FIG. 5. Further details associated with flexible display panel 10 are described in association FIGS. 3A and 3B.

FIGS. 3A and 3B are cross-sectional views of the flexible display panel of FIGS. 2A and 2B taken along sectional line III-III′, according to one or more exemplary embodiments. That is, FIG. 3A is a cross-sectional view of flexible display panel 10 in a non-bent state, and

FIG. 3B is a cross-sectional view of flexible display panel 10 in a second bent state.

Referring to FIGS. 1, 2A, 2B, 3A, and 3B, flexible display panel 10 includes display area DA in which display structure 20 is formed, and a non-display area disposed outside display area DA. Display area DA may also correspond to an active area, such as an active area of display structure 20, an active area of a touch sensing layer, etc. In this manner, the active area may be a region in which a function of flexible display panel 10 is provided to a user, such as a display function, a touch sensing function, etc. For descriptive and illustrative convenience, display area DA and the active area may be referred to as display area DA. The non-display area may include black matrix area BA through which one or more signal (or transmission) lines 12 pass, and pad area PA through which one or more signal lines 12 pass. It is noted that the non-display area may also correspond to an inactive area, such as an inactive area of display structure 20, an inactive area of a touch sensing layer, etc. In this manner, the inactive area may be a region in which the function provided in display area DA is not provided. For descriptive and illustrative convenience, the non-display area and the inactive area may be referred to as non-display areas, however, particular reference may be made to black matrix area BA and pad area PA. It is also noted that pad electrodes (or traces) 13 may be disposed in pad area PA to connect with one or more signal lines 12 disposed in pad area PA. It is also contemplated that pad electrodes 13 may form a portion of signal lines 12, e.g., a wider portion of signal lines 12.

Black matrix area BA may be disposed in association with multiple (e.g., two, three, etc.) edges of display area DA. As such, pad area PA may be disposed in association with at least one remaining area of display area DA. Pad area PA may have a larger width than a width of black matrix area BA. For example, black matrix area BA may be formed having a width on the order of 1 to 2 mm, whereas pad area PA may be formed having a width on the order of 3 to 5 mm. An integrated circuit chip (not shown), e.g., a main driver, a gate driver, a data driver, a power source, etc., may be mounted on (or coupled to) pad area PA.

For instance, the data driver and/or the gate driver may be coupled to a surface of a non-display area of flexible display panel 10 via a chip-on-plastic (COP) technique or a chip-on-film (COF) technique, and the main driver may be disposed on flexible printed circuit board 14 or printed circuit board 15. In one or more exemplary embodiments, a COP technique may include mounting an integrated circuit (IC) forming a driving circuit (e.g., the data driver, the gate driver, etc.) on flexible substrate 11 via a conductive film (not illustrated), such as an anisotropic conductive film. A COF technique may, for example, include mounting an IC forming a driving circuit (e.g., the data driver, the gate driver, etc.) on a film (not shown), the film being utilized to couple flexible printed circuit board 14 to flexible substrate 11. It is noted that the main driver may be connected to the data driver and the gate driver via signal lines 12 and pad electrodes 13.

Flexible printed circuit board 14 may include a flexible printed circuit and a multilayer printed circuit board; however, exemplary embodiments are not limited thereto or thereby. As another example, the data driver and/or the gate driver may be coupled to a non-display area of flexible display panel 10 via a tape-automated bonding (TAB) technique. In this manner, the main driver, the gate driver, and the data driver may be disposed on flexible printed circuit board 14 and/or printed circuit board 15, and, thereby, be electrically connected to one another. For instance, flexible printed circuit board 14 may include a tape carrier package (TCP) on which the data driver and/or the gate driver may be mounted, and a multilayer printed circuit board on which the main driver may be mounted. The multilayer printed circuit board may be connected to the TCP. Also, the power source (e.g., an external power source) may be connected to the main driver.

According to one or more exemplary embodiments, flexible display panel 10 may be a flexible organic light emitting display panel; however, exemplary embodiments are not limited thereto or thereby. When implemented as a flexible organic light emitting display panel, each pixel P of display structure 20 may include a pixel circuit (not shown) including at least one thin film transistor, at least one capacitor, and at least one organic light emitting diode, of which light emission is controlled, at least in part, via the pixel circuit. As previously mentioned, an exemplary pixel circuit is described in more detail with reference to FIG. 5. It is noted, however, that FIGS. 3A and 3B schematically illustrate display structure 20 including pixel circuit layer 21 and organic light emitting diode layer 22 as placeholders. A more detailed description of display structure 20 is provided in association with FIGS. 6A, 6B, and 6C.

With continued reference to FIGS. 3A and 3B, display structure 20 may be covered and sealed (e.g., hermetically sealed) via thin film encapsulation layer 23. Signal lines (e.g., signal line 12) may connect the pixel circuits of display area DA and pad electrodes (e.g., pad electrode 13) of pad area PA. Pad electrodes 13 arranged in pad area PA may be electrically and physically connected to signal lines 12 disposed at (or near) a first side of flexible printed circuit board 14 via an anisotropic conductive film, conductive traces, or the like. Signal lines 12 at a second side of flexible printed circuit board 14 may also be electrically and physically connected to printed circuit board 15 via an anisotropic conductive film, conductive traces, or the like. It is also contemplated that one or more of signal lines 12 may be connected to one or more pixels P, but not connected to at least one of the main driver, the gate driver, the data driver. In this manner, signal lines 12 may generally be disposed in the non-display area and extend into display area DA. Although signal lines 12 are illustrated in FIG. 1 as crossing bending line BL at various angles, it is contemplated that signal lines 12 may extend across bending line BL in first direction D1, e.g., in a direction perpendicular to bending line BL. Further, signal lines 12 may be connected to or form signal lines disposed in display area DA, such as gate lines, data lines, and data voltage lines. In this manner, a control signal output from flexible printed circuit is board 14 and/or printed circuit board 15 may be transmitted to a pixel circuit disposed in display area DA via at least one of flexible printed circuit board 14 and signal line 12. The control signal may be selectively applied to pixels P based on the operation of the one or more thin film transistors of the pixel circuits. It is contemplated, however, that a COP, COF, etc., structure including an integrated circuit chip may be utilized, as previously mentioned.

As seen in FIG. 3B, pad area PA may be deformed (e.g., folded, bent, curved, etc.) from plane PL tangent to a surface of display area DA to, for example, enhance aesthetics of flexible display panel 10 when incorporated as part of an electronic device. Plane PL extends in first and second directions D1 and D2. In one or more exemplary embodiments, pad area PA may be bent from plane PL, and, thereby, bent about bending axis BX. As such, pad area PA may be bent back towards display area DA, such that display area DA is disposed over printed circuit board 15 in third direction D3. With reference to FIGS. 2A and 3A, pad area PA may extend, in a non-bent state, from display area DA along plane PL, and, as such, may include an imaginary bending line BL extending in second direction D2. In this manner, pad area PA may be folded or bent at (or in association with) bending line BL such that printed circuit board 15 is rotated with respect to bending line BL in, for example, a clockwise direction. Deformation of pad area PA may cause display area DA to be disposed over printed circuit board 15.

According to one or more exemplary embodiments, flexible substrate 11 is configured to be deformed (e.g., bent along bending line BL) relatively easily when no external factor interrupts the deformation of flexible substrate 11. As such, pad area PA may be easily folded or bent under display area DA. It is noted, however, that the ease with which flexible substrate 11 is deformed may be contingent upon the presence (or paucity) of external factors interrupting the bending, such as an integrated circuit chip disposed on bending line BL or the rigidity of flexible substrate 11 and/or one or more layers formed on flexible substrate 11. As such, integrated circuit chips disposed in pad area PA may be disposed in a portion of pad area PA at a sufficient distance from bending line BL so that pad area PA may be sufficiently bent along bending line BL. In this manner, deformation of pad area PA may cause a portion of flexible printed circuit board 14 to also be deformed. At least a portion of flexible printed circuit board 14 and printed circuit board 15 may be disposed under or behind display area DA. It is contemplated that flexible substrate 11 is sufficiently elastic to enable flexible substrate 11 to remain in the deformed portions of pad area PA. As such, flexible substrate 11 may support signal lines 12 disposed thereon, and, thereby, protect signal lines 12 from (or reduce the potential for) damage that may otherwise occur when an external force is applied to pad area PA, whether intentional or unintentional. For instance, the external force may be the result of a later performed manufacturing process, an accident, etc.

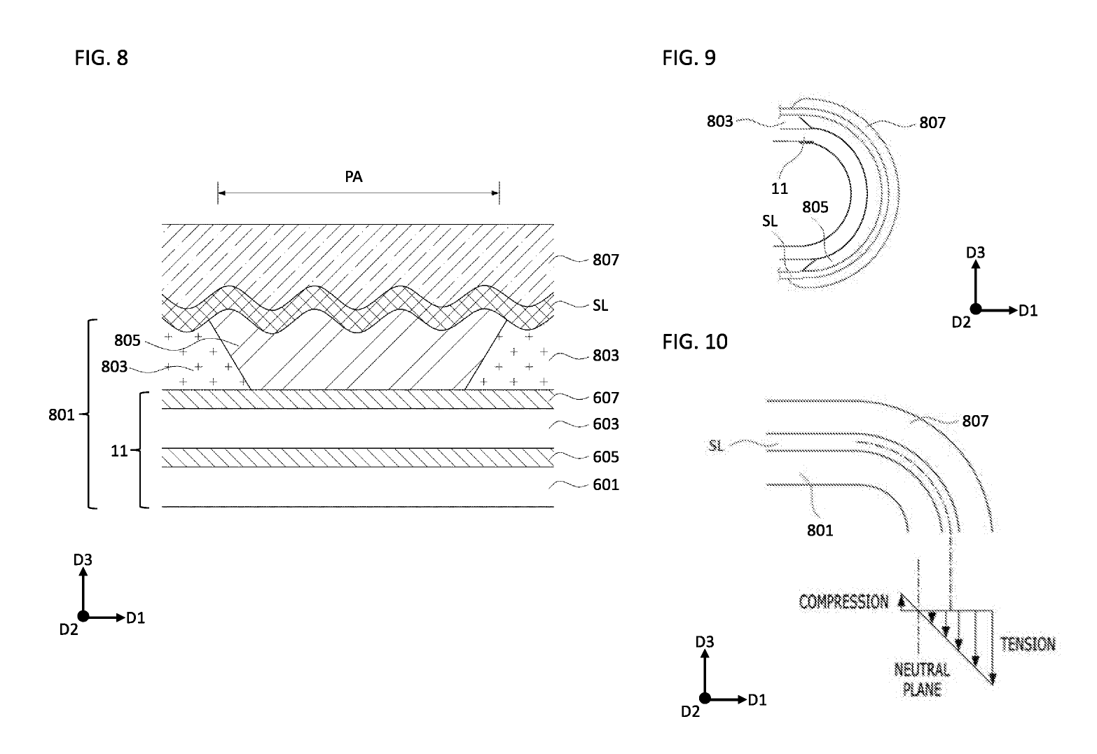

In one or more exemplary embodiments, as pad area PA is deformed along bending line BL, portion PA1 of pad area PA extending from display area DA may remain visible to an observer when flexible substrate 11 is viewed in a plan view, e.g., in third direction D3. That is, portion PA1 of pad area PA may not be disposed under display area DA. As seen in FIG. 1, “w1” indicates a width of portion PA1. Width w1 of portion PA1 may be on the order of 1 to 2 mm, which may be the same as the width of black matrix area BA. It is also contemplated that width w1 of portion PA1 may be substantially zero in non-bezel configuration. In this manner, a bend radius of pad area PA with respect to bend axis BX and lower surface 11a of flexible substrate 11 may be greater than or equal to 250 μm and less than or equal to 300 μm. As such, the amount of non-display area visible to an observer may be reduced, and a bezel area of display device 100 may also be reduced in comparison to a conventional display device. A bending (or curved) portion of pad area PA is described in more detail with FIGS. 8-15.

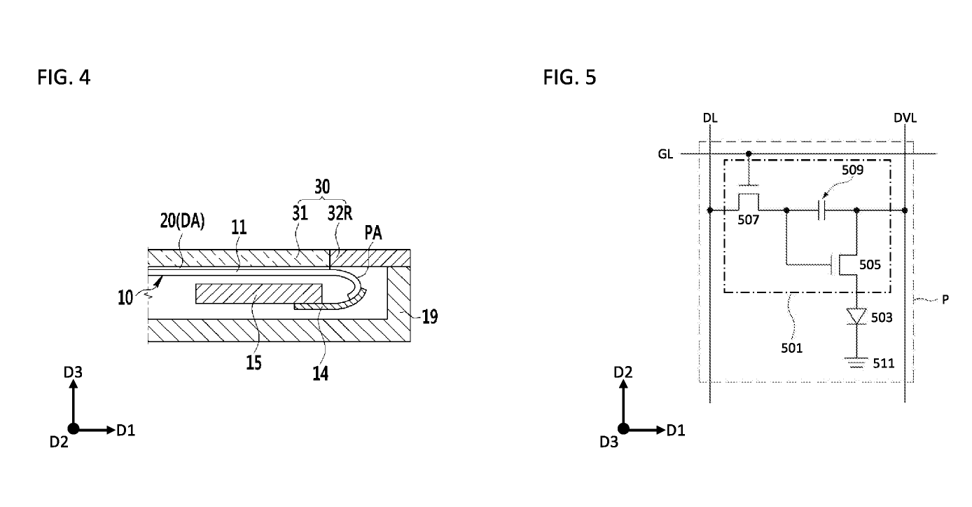

FIG. 4 is a partial cross-sectional view of an assembled state of the display device of FIG. 1, according to one or more exemplary embodiments.

Referring to FIGS. 1 and 4, cover window 30 may include transparent area 31 overlapping display area DA, and opaque bezel area 32 overlapping the non-display area. Given that pad area PA may be folded or bent under display area DA, the non-display area may correspond to black matrix area BA and portion PA1. That is, bezel area 32 may correspond to black matrix area BA and portion PA1. In one or more exemplary embodiments, cover window 30 may include any suitable material, such as at least one of high strength tempered glass, poly (methyl methacrylate), polycarbonate, etc. To this end, cover window 30 may be at least scratch resistant. Cover window 30 may be coupled to flexible display panel 10 and case 19, which may receive and support various other components of display device 100.

According to one or more exemplary embodiments, bezel area 32 may include various portions, such as upper bezel area (or portion) 32U, lower bezel area (or portion) 32D, left bezel area (or portion) 32L, and right bezel area (or portion) 32R. It is noted, however, that the various portions of bezel area 32 may be alternatively configured and/or referenced in any other suitable manner. As seen in FIGS. 1 and 4, upper and lower portions 32U and 32D of bezel area 32 may be referred to as such based on a viewpoint of an onlooker observing cover window 30 in third direction D3. It is also noted that upper and lower portions 32U and 32D of bezel area 32 may be referred to as such based on an orientation of display device 100 when, for example, at least one character (e.g., an alphanumeric character) is displayed in an erect, upright, and readable manner, such as, not in a rotated or up-side-down manner. As such, left and right portions 32L and 32R of bezel area 32 may be disposed orthogonal to upper and lower portions 32U and 32D. Exemplary embodiments, however, are not limited thereto or thereby. For instance, one or more of upper bezel area (or portion) 32U, lower bezel area (or portion) 32D, left bezel area (or portion) 32L, and right bezel area (or portion) 32R may be omitted.

Although not illustrated, an electronic device including display device 100 may include various other components, such as, for example, a speaker, a camera, a proximity sensor, a physical button, a capacitive button, a microphone, etc., and/or combinations thereof. To this end, the components may be disposed on or behind bezel area 32 of cover window 30. When, for example, display device 100 is included as part of a mobile device, these “other” components may be disposed in association with upper bezel area 32U and lower bezel area 32D, which may enhance the visual and ergonomic appeal of the mobile device.

According to one or more exemplary embodiments, portion PA1 may contact a side portion (e.g., a left end portion or a right end portion) of display area DA. That is, portion PA1 may not be disposed behind lower bezel area 32D, but may be disposed behind one of left bezel area 32L and right bezel area 32R. FIGS. 1 and 4 provide an illustrative example of portion PA1 being disposed behind right bezel area 32R. It is noted, however, that left bezel area 32L and right bezel area 32R may correspond to black matrix area BA and portion PA1. In this manner, visual and ergonomic appeal of an electronic device including display device 100 may be enhanced by at least reducing widths of left bezel area 32L and right bezel area 32R.

In one or more exemplary embodiments, lower bezel area 32D may or may not include a component or part covering pad area PA (unlike in a conventional display device). As such, a width of lower bezel area 32D may be sized in consideration of “other” components disposed in association therewith, and, thereby, made smaller than conventional lower bezel areas. In addition, one or more exemplary embodiments enable a width of upper bezel area 32U to be reduced in accordance with the width of lower bezel area 32D. That is, the width of upper bezel area 32U may be the same as (or at least similar to) the width of lower bezel area 32D.

According to one or more exemplary embodiments, portion PA1 may be disposed behind lower bezel area 32D. It is noted, however, that since various “other” components of an electronic device including the display device 100 may be disposed behind lower bezel area 32D, a defect may be generated due, at least in part, to interference between portion PA1 and the “other” components. Further, in conventional flexible display panels, a substrate may be removed, notched, patterned, etc., in pad area PA to enable an associated display panel to be more easily deformed and to alter a location of a neutral plane of pad area PA when pad area PA is bent. The removal, notching, patterning, etc., of the substrate may leave pad area PA subject to defects (or damage) from external forces.

For instance, the curvature of pad area PA may be unintentionally deformed as the result of an external impact (e.g., an impact associated with a later performed manufacturing process) or user interaction with display device 100. These unintentional deformations may cause cracks and delamination defects to be generated, as well as increase resistance of signal lines 12 passing through pad area PA. To this end, installation of a structure to support pad area PA may be relatively difficult or undesirable at least because the structure may consume valuable real estate that may otherwise accommodate “other” components of an electronic device. As will become more apparent below, the symmetrical ordering of layers disposed above and below signal line 12 in pad area PA may cause, at least in part, a neutral plane to extend through signal line 12 when pad area PA is bent about bending axis BX. This configuration may enable stress or strain applied to signal line 12 in pad area PA to be reduced or at least partially eliminated. It is also noted that because flexible substrate 11 remains in pad area PA, signal line 12 may be sufficiently supported, and, thereby, protected from defects that might otherwise occur as the result of external forces being applied to pad area PA after being bent.

Moreover, given that “other” components of an electronic device including display device 100 may not be disposed behind left and right bezel areas 32L and 32R of bezel area 32, interference between portion PA1 and the “other” components may be prevented or at least reduced. Further, flexible substrate 11 supporting pad area PA may remain, and, thereby, reduce dependency on the installation of additional support structures that might otherwise consume valuable real estate. Further, pad area PA of display device 100 may be bent at a smaller bend radius given that a neutral plane of pad area PA may extend through signal lines 12, and, thereby, reduce the amount of stress and/or strain that would otherwise affect the reliability and performance of signal lines 12. As such, not only do exemplary embodiments minimize a width of portion PA1 and reduce an overall thickness of flexible display panel 10, but exemplary embodiments also enable portion PA1 to be positioned to avoid or reduce interference with “other” components of an electronic device including display device 100. As such, generation of defects may be prevented or reduced. Again, more detailed descriptions of the configuration of pad area PA are provided in association with FIGS. 8-15.

As may be appreciated from FIG. 1, display area DA may be formed according to a portrait configuration including longitudinal lengths of upper and lower bezel areas 32U and 32D being smaller than longitudinal lengths of left and right bezel areas 32L and 32R. It is noted, however, that display area DA may be formed according to a landscape configuration with longitudinal lengths of left and right bezel areas 32L and 32R being smaller than longitudinal lengths of upper and lower bezel areas 32U and 32D. Furthermore, bending line BL of FIGS. 2A and 2B may be displaced in first direction D1 to overlap a portion of display area DA. In this manner, a portion of display area DA may be bent with pad area PA to form a bezel-less display device 100 with respect to the left and right lateral edges of display device 100. That is, when flexible display panel 10 includes bending line BL overlapping display area DA and incorporated into a corresponding electronic device, left and right lateral edges of display area DA may not only extend to corresponding left and right lateral edges of the electronic device, but may wrap past the left and right lateral edges of the electronic device. As such, lateral portions of display area DA may be disposed on left and right lateral side surfaces of the electronic device, which may further increase the visual and ergonomic appeal of display device 100. It is noted, however, that flexible display panel 100 may be bent at angles greater than 0 degrees and less than or equal to 360 degrees, e.g., at angles greater than 0 degrees and less than or equal to 270 degrees. It is also noted that any number of sides of flexible display panel 10 may be bent.

FIG. 5 is an equivalent circuit diagram of a pixel of the flexible display panel of FIGS. 2A and 2B, according to one or more exemplary embodiments. It is noted that pixel P of FIG. 5 is representative of the various pixels of flexible display panel 10. To this end, one or more of the signal lines of FIG. 5 (e.g., gate line GL, data line DL, and data voltage line DVL) may correspond to portions of signal lines 12 of FIGS. 2A, 2B, 3A, and 3B.

According to one or more exemplary embodiments, pixel P includes pixel circuit 501 connected to gate line GL extending in first direction D1, data line DL extending in second direction D2, and driving voltage line DVL extending in second direction D2. Second direction D2 may cross first direction D1. Organic light emitting diode 503 is connected to pixel circuit 501. Pixel circuit 501 includes driving thin film transistor (TFT) 505, switching TFT 507, and storage capacitor 509. Although reference will be made to this particular implementation, it is also contemplated that pixel circuit 501 may embody many forms and include multiple and/or alternative components and configurations. As such, the equivalent circuit diagram of FIG. 5 is merely illustrative; exemplary embodiments are not limited thereto or thereby.

In one or more exemplary embodiments, switching TFT 507 includes a first electrode connected to gate line GL, a second electrode connected to data line DL, and a third electrode connected to a first electrode of storage capacitor 509 and a first electrode of driving TFT 505. In this manner, switching TFT 507 is configured to transfer a data signal Dm received via data line DL to driving TFT 505 in response to a scan signal Sn received via gate line GL. As previously mentioned, the first electrode of storage capacitor 509 is connected to the third electrode of switching TFT 507. A second electrode of storage capacitor 509 is connected to driving voltage line DVL and a second electrode of driving TFT 505. As such, storage capacitor 509 is configured to store a voltage corresponding to a difference between a voltage received via switching TFT 507 and a driving voltage ELVDD received via driving voltage line DVL.

The second electrode of driving TFT 505 is connected to driving voltage line DVL and the second electrode of storage capacitor 509. Driving TFT 505 also includes a first electrode connected to the third electrode of switching TFT 507 and a third electrode connected to a first electrode of organic light emitting diode 503. In this manner, driving TFT 505 is configured to control a driving current through organic light emitting diode 503 from driving voltage line DVL in response to the voltage value stored in storage capacitor 509. The organic light emitting diode 503 includes a first electrode connected to the third electrode of driving TFT 505 and a second electrode connected to common power voltage 511, e.g., a common power voltage ELVSS. As such, organic light emitting diode 503 may emit light at a determined brightness (and, in one or more exemplary embodiments, a determined color) according to the driving current received via driving TFT 505.

FIG. 6A is an enlarged view of portion A of the flexible display panel of FIG. 3A, according to one or more exemplary embodiments. FIGS. 6B and 6C are enlarged views of portion B of a flexible substrate of the flexible display panel of FIG. 6A, according to one or more exemplary embodiments. The cross-section illustrated in FIG. 6A may correspond to a pixel or a sub-pixel of flexible display panel 10. For descriptive and illustrative convenience, a sub-pixel implementation is described below.

According to one or more exemplary embodiments, sub-pixels of flexible display panel 10 may include at least one thin-film transistor TFT and an organic light-emitting device connected to thin-film transistor TFT. For instance, thin-film transistor TFT of FIG. 6A may correspond to driving TFT 505 of FIG. 5. Thin-film transistor TFT is not limited to having the structure shown in FIG. 6A, and a number and a structure of thin-film transistor TFT may be variously modified. As seen in FIG. 6A, flexible display panel 10 may include flexible substrate 11, display structure 20, and thin film encapsulation layer 23.

Flexible substrate 11 may be formed of one or more flexible insulating materials, and, in one or more exemplary embodiments, may include multiple layers stacked on one another in third direction D3. For instance, flexible substrate 11 may include one or more inorganic layers and one or more organic layers. As seen in FIGS. 6B and 6C, flexible substrates 11 and 11′ include organic layers 601 and 603 and inorganic layers 605 and 607 forming respective stacks. Although two organic layers and two inorganic layers are shown, it is contemplated that any suitable number of organic layers and inorganic layers may be utilized in association with exemplary embodiments. It is also noted that flexible substrate 11 may be transparent, translucent, or opaque.

Organic layers 601 and 603 may be formed of any suitable organic material, such as, for example, a polyester-based polymer, a silicone-based polymer, an acrylic polymer, a polyolefin-based polymer, or a copolymer thereof. For instance, organic layers 601 and/or 603 may be formed of one or more of polyimide (PI), polycarbonate (PC), polyethersulphone (PES), polybutylene terephthalate (PBT), polyethylene terephthalate (PET), polyethylene naphthalate (PEN), polyarylate (PAR), polysilane, polysiloxane, polysilazane, polycarbosilane, polyacrylate, polymethacrylate, polymethylacrylate, polyethylacrylate, polyethylmethacrylate, a cyclic olefin copolymer (COC), a cyclic olefin polymer (COP), polyethylene (PE), polypropylene (PP), polymethylmethacrylate (PMMA), polystyrene (PS), polyacetal (POM), polyether ether ketone (PEEK), polytetrafluoroethylene (PTFE), polyvinylchloride (PVC), polyvinylidenefluoride (PVDF), a perfluoroalkyl polymer (PFA), a styrene acrylonitrile copolymer (SAN), a fiber glass reinforced plastic (FRP), and the like. It is also contemplated that organic layers 601 and 603 may be glass substrates with thicknesses to such a degree that flexible substrate 11 may be bent.

Inorganic layers 605 and 607 may be formed of any suitable inorganic material, such as, for example, amorphous silicon (a-Si), silicon oxide (SiOₓ), silicon nitride (SiNₓ), silicon oxynitride (SiOₓN_{y}), aluminum oxide (AlOₓ), aluminum oxynitride (AlOₓN_{y}), etc. In this manner, inorganic layers 605 and 607 may obstruct permeation of oxygen, moisture, and the like, and may planarize a surface of flexible substrate 11. As such, at least one of inorganic layers 605 and 607 may also be referred to as a buffer layer and/or a barrier layer.

As seen in FIG. 6B, flexible substrate 11 may include inorganic layer 607 disposed on organic layer 603, which is disposed on inorganic layer 605 that is disposed on organic layer 601. In other words, inorganic layer 607, organic layer 603, inorganic layer 605, and organic layer 601 may be sequentially disposed on one another. In this manner, flexible substrate 11 may be formed as an organic-inorganic layer stack. Exemplary embodiments, however, are not limited thereto or thereby.

For example, in FIG. 6C, flexible substrate 11′ may include inorganic layers 605 and 607 stacked between organic layers 601 and 603. To this end, flexible substrate 11′ may further include one or more conductive layers SL disposed between inorganic layers 605 and 607. Conductive layer SL may include (or define) one or more signal lines 12 connected between pixels P of flexible display panel 10 and one or more driving components, such as the aforementioned main driver, data driver, gate driver, and power source. As such, flexible substrate 11′ may include organic layer 603, inorganic layer 607, conductive layer SL, inorganic layer 605, and organic layer 601 sequentially disposed on one another. To this end, conductive layer SL may be symmetrically ordered in an organic-inorganic layer stack, such that a first organic layer (e.g., organic layer 603) and a first inorganic layer (e.g., inorganic layer 607) are disposed above conductive layer SL, and a second organic layer (e.g., organic layer 601) and a second inorganic layer (e.g., inorganic layer 605) are disposed below conductive layer SL. In this manner, the order of the organic and inorganic layers may mirror itself about conductive layer SL, such that conductive layer SL is disposed between inorganic layers 605 and 607, and inorganic layers 605 and 607 are disposed between organic layers 601 and 603. It is noted that a combined thickness of inorganic layer 605, conductive layer SL, and inorganic layer 607 may be greater than or equal to 100 nm and less than or equal to 900 nm, such as greater than or equal to 300 nm and less than or equal to 800 nm, e.g., greater than or equal to 700 nm and less than or equal to 800 nm. Exemplary embodiments, however, are not limited thereto or thereby. At least one effect of the above-noted stacking orders of FIGS. 6B and 6C will be apparent in association with FIGS. 12 and 15.

Referring to FIGS. 6A to 6C, thin-film transistor TFT may be formed on organic layer 603 or inorganic layer 607, at least one of which may function as a buffer layer. As seen in FIG. 6A, thin-film transistor TFT is shown as a top-gate transistor; however, a thin-film transistor having any other suitable structure, such as a bottom-gate transistor, may be utilized in association with exemplary embodiments.

Active layer 609 with a patterned configuration is disposed on flexible substrate 11. Gate insulating layer 611 covers active layer 609. Gate insulating layer 611 may be formed of any suitable inorganic material, such as silicon oxide, silicon nitride, etc. To this end, gate insulating layer 611 may include one or more layers, and at least one of the one or more layers may be formed from a different material than at least one other layer of the one or more layers of gate insulating layer 611. Active layer 609 includes source area 609s spaced apart from drain area 609d by channel area 609c.

According to one or more exemplary embodiments, active layer 609 may be formed of any suitable semiconductor material. For example, active layer 609 may contain an inorganic semiconductor material, such as amorphous silicon or polysilicon crystallized from amorphous silicon. Active layer 609 may contain an oxide semiconductor material, such as an oxide of a material selected from a group XII, XIII, or XIV element, such as zinc (Zn), indium (In), gallium (Ga), tin (Sn), cadmium (Cd), germanium (Ge), and hafnium (Hf), or combinations thereof. Further, active layer 609 may be formed of a relatively low polymer-series or polymer-series organic material, such as mellocyanine, phthalocyanine, pentacene, thiophen, and the like.

Gate electrode 613 of thin film transistor TFT is disposed on gate insulating layer 611, and overlaps channel region 609c of active layer 609. Interlayer dielectric layer 615 covers gate electrode 613 and is disposed on an exposed surface of gate insulating layer 611. In one or more exemplary embodiments, interlayer dielectric layer 615 may be formed of an organic material, e.g., polyimide, or an inorganic material, such as silicon oxide, silicon nitride, phosphorsilicate glass, borophosphosilicate glass, etc., or combinations thereof. In this manner, interlayer dielectric layer 615 may be formed via chemical vapor deposition or a spin coating technique, however, any other suitable method to form interlayer dielectric layer 615 may be used in association with exemplary embodiments. As such, interlayer dielectric layer 615 may be formed with a substantially flat surface. It is noted that contact holes 617 and 619 are formed in interlayer dielectric layer 615 and gate insulating layer 611. Source electrode 621 and drain electrode 623 are disposed on interlayer dielectric layer 615, and respectively extend into contact holes 619 and 617. As such, source electrode 621 contacts source area 609s via contact hole 619, and drain electrode 623 contacts drain area 609d via contact hole 617.

According to one or more exemplary embodiments, gate electrode 613, source electrode 621, and/or drain electrode 623 may be formed as a single or multiple layer structure, as may gate lines GL, data lines DL, and data voltage lines DVL. In one or more exemplary embodiments, signal lines 12 and, thereby, conductive layer SL, may also be formed as a single or multiple layer structure. For example, gate electrode 613, source electrode 621, and drain electrode 623 may be formed of any suitable conductive material, such as molybdenum (Mo), nickel (Ni), chromium (Cr), tungsten (W), silver (Ag), gold (Au), titanium (Ti), copper (Cu), aluminum (Al), neodymium (μl-Nd), etc., or alloys thereof. Multilayer structures may include dual layer structures including Mo/Al-μl-Nd, Mo/Al, Ti/Al, etc. It is also contemplated that the multilayer structures may include layer formations of Mo/Al/Mo, Mo/Al-μl-Nd/Mo, Ti/Al/Ti, Ti/Cu/Ti, etc. Further, silver nanowire (Ag-NW) may be used in association with one or more exemplary embodiments.

According to one or more exemplary embodiments, a material of gate electrode 613 may be different than a material of source electrode 621 and drain electrode 623. Further, the number of conductive layers forming gate electrode 613 may be different than a number of conductive layers forming source electrode 621 and drain electrode 623. In this manner, the materials and layer configuration of conductive layer SL (and, thereby, signal lines 12) may correspond to the materials and layer configuration of at least one of gate electrode 613, source electrode 621, and drain electrode 623. It is also contemplated that the materials and layer configuration of conductive layer SL may be different from gate electrode 613, source electrode 621, and drain electrode 623.

Passivation layer 625 is disposed on thin-film transistor TFT and interlayer dielectric layer 615. In one or more exemplary embodiments, passivation layer 625 may be a planarization film that functions to reduce steps in one or more underlying layers and also serves to protect the one or more underlying layers. To this end, passivation layer 625 may be formed of any suitable organic insulating material, such as a positive or a negative photosensitive organic insulating film. It is also contemplated that passivation layer 625 may be formed from an inorganic material, such as silicon nitride.

As seen in FIG. 6A, pixel electrode 627 is formed on passivation layer 625. Pixel electrode 627 may be a transparent (or translucent) electrode or a reflective electrode. When pixel electrode 627 is a transparent (or translucent) electrode, pixel electrode 627 may be formed of, for example, indium tin oxide (ITO), indium zinc oxide (IZO), zinc oxide (ZnO), indium oxide (In₂O₃), indium gallium oxide (IGO), aluminum zinc oxide (AZO), etc. When pixel electrode 627 is a reflective electrode, pixel electrode 627 may include a reflective layer formed of Ag, magnesium (Mg), Al, platinum (Pt), palladium (Pd), Au, Ni, neodymium (Nd), iridium (Ir), Cr, calcium (Ca), silicon (Si), sodium (Na), W, or a compound thereof, and a layer formed of ITO, IZO, ZnO, SnO, In₂O₃, TiₓO_{y}. In this manner, pixel electrode 627 may be formed with a single layer or a multiple layer configuration. For instance, pixel electrode 627 may include a layer formation of ITO/Si/ITO, TiₓO_{y}/Ag/TiₓO_{y}, etc. A thickness of pixel electrode 627 may range from 100 to 300 nm; however, exemplary embodiments of pixel electrode 627 are not limited to or by the above-noted examples.

According to one or more exemplary embodiments, pixel electrode 627 contacts drain electrode 623 of thin-film transistor TFT through via hole 629 formed in passivation layer 625. As previously mentioned, passivation layer 625 may be formed of an inorganic and/or organic material, or formed with a single layer or multiple layers. Passivation layer 625 may be formed as a planarization layer so that a top surface is smooth regardless of unevenness of one or more lower layers. Passivation layer 625 may also be formed to be uneven according to unevenness of at least one layer below passivation layer 625. In addition, passivation layer 625 may be formed of a transparent insulator, and, as such, may provide a resonant effect.

Pixel-defining layer 630 is formed on pixel electrode 627 and passivation layer 625. In this manner, pixel-defining layer 630 is patterned to include an opening to expose a portion of pixel electrode 627. For instance, the opening may be 10 to 20 μm wide. According to one or more exemplary embodiments, pixel-defining layer 630 may be formed of an organic and/or inorganic material. For example, pixel-defining layer 630 may be formed of polyimide. It is noted that a coefficient of thermal expansion (CTE) of the polyimide of pixel-defining layer 630 may be different than a CTE of the polyimide used to form at least one layer in flexible substrate 11. According to one or more exemplary embodiments, the CTE of the polyimide of pixel-defining layer 630 may be greater than or equal to 10×10⁻⁶K⁻¹ and less than or equal to 20×10⁻⁶K⁻¹, whereas the CTE of the polyimide of flexible substrate 11 may be greater than or equal to 3×10⁻⁶K⁻¹ and less than or equal to 5×10⁻⁶K⁻¹. To this end, the polyimide used to form at least one layer in flexible substrate 11 may have a different modulus of elasticity than the polyimide used to form pixel-definition layer 630.

Although not illustrated, one or more protrusions may be formed on (or as part of) an upper surface of pixel definition layer 630 to facilitate reliable manufacture of intermediate layer 631. It is noted that the protrusions may be formed of any suitable organic material, such as one or more of the previously mentioned organic materials.

According to one or more exemplary embodiments, intermediate layer 631 and opposite electrode 633 are formed on pixel electrode 627. In this manner, pixel electrode 627 may function as an anode electrode of an organic light emitting diode (e.g., organic light emitting diode 503 of FIG. 5), and opposite electrode 633 may function as a cathode electrode of the organic light emitting diode. It is contemplated, however, that the polarities of pixel electrode 627 and opposite electrode 633 may be reversed. Pixel electrode 627 and opposite electrode 633 are insulated from each other via intermediate layer 631. An organic emission layer of intermediate layer 631 may emit light according to voltages of different polarities being applied to intermediate layer 631. In one or more exemplary embodiments, intermediate layer 631 may include an organic emission layer. As another example, intermediate layer 631 may include the organic emission layer, and further include at least one layer selected from the group consisting of a hole injection layer (HIL), a hole transport layer (HTL), an electron transport layer (ETL), and an electron injection layer (EIL).

Although a light emitting material may be separately included in respective sub-pixels of the organic light emission layer, exemplary embodiments are not limited thereto or thereby. The organic light emission layer may be a common organic light emission layer used in association with each pixel P regardless of the location of the pixel P. In one or more exemplary embodiments, the organic light emission layer may include light emitting materials to emit red light, green light, and blue light, respectively; however, any other suitable color may be utilized in association with exemplary embodiments. The light emitting materials may be stacked in a vertical direction, e.g., third direction D3, or disposed in a mixed manner. The light emitting materials may include materials to emit a combination of different colors. The combination of different colors may be utilized to form white light. Although not illustrated, a color conversion layer or a color filter may be included to convert the emitted white light to a certain color.

Thin film encapsulation layer 23 may be formed on display structure 20. In one or more exemplary embodiments, thin film encapsulation layer 23 may include a plurality of inorganic layers, or an inorganic layer and an organic layer. For instance, an organic layer of thin film encapsulation layer 23 may be formed of a polymer material, and may be a single layer formed of one selected from polyethylene terephtalate, polyimide, polycarbonate, epoxy, polyethylene, and polyacrylate, or layers in which one or more of the aforementioned materials are stacked on top of one another. The organic layer may be formed of polyacrylate, and may include a material formed by polymerizing a monomer composition that includes a diacrylate-based monomer and a triacrylate-based monomer. A monoacrylate-based monomer may be further included in the monomer composition. To this end, a photoinitiator, such as a thermoplastic polyolefin (TPO), may be included in the monomer composition. It is noted, however, that the monomer composition is not limited to or by the aforementioned examples, and may include epoxy, polyimide, polyethylene terephthalate, polycarbonate, polyethylene, polyacrylate, or the like.

According to one or more exemplary embodiments, the organic layer included in thin film encapsulation layer 23 may be a single layer or multiple stacked layers that include a metal oxide or metal nitride, e.g., an inorganic layer. For example, the inorganic layer may include one selected from SiOₓ, SiNₓ, Al₂O₃, titanium oxide (TiO₂), zirconium oxide (ZrOₓ), and ZnO. An uppermost layer of thin film encapsulation layer 23 that is exposed to an ambient environment, may be formed of an inorganic layer, which may prevent or reduce moisture from permeating to intermediate layer 631.

Thin film encapsulation layer 23 may include at least one sandwich structure in which at least one organic layer is disposed between at least two inorganic layers. As another example, thin film encapsulation layer 23 may include at least one sandwich structure in which at least one inorganic layer is inserted between at least two organic layers. For example, thin film encapsulation layer E may include a first inorganic layer, a first organic layer, a second inorganic layer, a second organic layer, a third inorganic layer, and a third organic layer sequentially formed from a surface of opposite electrode 633. It is noted, however, that a halogenated metal layer that includes lithium-fluoride (LiF) may be further included between opposite electrode 633 and the first inorganic layer. The halogenated metal layer may prevent (or reduce) damage to intermediate layer 633 when the first inorganic layer is formed using, for example, a sputtering method. An area of the first organic layer may be smaller than an area of the second inorganic layer, and an area of the second organic layer may be smaller than an area of the third inorganic layer. It is contemplated, however, that thin film encapsulation layer 23 is not limited thereto or thereby. For instance, thin film encapsulation layer 23 may include any structure in which an inorganic layer and an organic layer are stacked on top of one another.

Although not illustrated, a protection layer may be formed on thin film encapsulation layer 23. The protection layer may be formed using various methods. For example, the protection layer may be formed using a sputtering method, an ion beam deposition method, an evaporation method, a chemical vapor deposition method, or the like. The protection layer may include a metallic oxide or nitride, such as SiNₓ, SiOₓN_{y}, titanium oxide (TIOₓ), titanium nitride (TINₓ), titanium oxynitride (TiOₓN_{y}), ZrOₓ, tantalum nitride (TaNₓ), tantalum oxide (TaOₓ), hafnium oxide (HfOₓ), AlOₓ, or the like. The protection layer may be formed to surround (e.g., completely surround) thin film encapsulation layer 23. In this manner, the protection layer P may increase life expectancy of thin film encapsulation layer 23 by obstructing the permeation of moisture and oxygen into thin film encapsulation layer 23.

FIG. 7 is a flowchart of a process for forming a flexible display panel with at least one bending portion, according to one or more exemplary embodiments. The process of FIG. 7 will be described in association with FIGS. 1, 3A, 3B, and 5. It is noted that the process of FIG. 7 will also be described in association with bending portion PA1 of pad area PA, however, it is contemplated that one or more additional or other areas of the non-display area or display area DA may be bent in association with exemplary embodiments.

In step 701, one or more display structures, such as thin-film transistor structures, storage capacitor structures, organic light-emitting diode structures, gate lines GL, data lines DL, data voltage lines DVL, signal lines 12, signal lines SL, and the like, may be formed on flexible substrate 11, which may be formed according to a structure described in FIGS. 6A and 6B. It is noted that organic layers 601 and 603 may be formed of polyimide. Although not illustrated, it is noted that flexible substrate 11 may be attached to a carrier substrate, such as a glass carrier substrate. In this manner, flexible display panel 10 may be partially formed including display area DA and the non-display area. At step 703, one or more ICs, which may include at least one driver configured to cause, at least in part, pixels P to display an image, may be coupled to flexible substrate 11, flexible printed circuit board 14, printed circuit board 15, etc. For instance, an IC may be coupled to flexible substrate 11 in portion PA1 of pad area PA. The glass carrier substrate may be removed, e.g., delaminated, from flexible substrate 11, per step 705. It is noted that, unlike conventional manufacturing processes, a supporting layer need not be attached to flexible substrate 11 after the carrier substrate is removed. In step 707, flexible printed circuit board 14 may be coupled to flexible substrate 11 via, for instance, conductive adhesive. It is noted that printed circuit board 15 may be coupled to flexible printed circuit board 14 before flexible printed circuit board 14 is coupled to flexible substrate 11. Exemplary embodiments, however, are not limited thereto or thereby.

In one or more exemplary embodiments, portion PA1 of pad area PA may be bent with respect to display area DA, at step 709. For example, portion PA1 may be bent with respect to plane PL tangent to a surface of display area DA. To this end, portion PA1 may be bent about bending axis BX, such that at least some of flexible printed circuit board 14 is disposed under display area DA. It is contemplated, however, that any other suitable bending configuration may be utilized in association with exemplary embodiments. To reduce mechanical stress and/or strain applied to signal lines 12 passing through pad area PA when pad area PA is bent, a structure of pad area PA may be configured to cause, at least in part, a neutral plane of pad area PA to extend through or at least gravitate towards signal line 12. Exemplary configurations of pad area PA including signal line 12 in a conductive layer SL that are configured to reduce mechanical stress and/or strain applied to signal lines 12 are described with FIGS. 8-15.

FIG. 8 is an enlarged view of portion C in a bending portion of the flexible display panel of FIG. 3A, according to one or more exemplary embodiments. FIG. 9 is a partial cross-sectional view of the bending portion of the flexible display panel of FIGS. 3B and 8, according to one or more exemplary embodiments. FIG. 10 schematically illustrates a neutral plane of the bending portion of the flexible display panel of FIGS. 8 and 9, according to one or more exemplary embodiments. Various layers of pad portion PA are similar to layers described in association with portion A of flexible display panel 10. As such, duplicative descriptions are primarily omitted to avoid obscuring exemplary embodiments.

Referring to FIGS. 3A, 5, 6A, 8, and 9, conductive layer SL may electrically connect printed circuit board 15 to one or more components of pixel P disposed in display area DA, such as driving TFT 505, switching TFT 507, organic light emitting diode 503, etc., of pixel P. Conductive layer SL may be formed with the same materials and layer configuration of at least one of gate electrode 613, source electrode 621, and drain electrode 623. In this manner, conductive layer SL may be formed on a same layer as gate electrode 613 or on a same layer as source electrode 621 and drain electrode 623. As such, conductive layer SL may be disposed on flexible substrate 11 with at least one inorganic layer 803 and/or organic layer 805 disposed between conductive layer SL and flexible substrate 11. Due, at least in part, to the presence of features underlying conductive layer SL (such as inconsistencies and/or bumps formed in and between layers of flexible substrate 11) and/or intentional patterning of the surfaces of at least one of inorganic layer 803 and organic layer 805, conductive layer SL may include undulating surfaces. The undulation of the surfaces of conductive layer SL may reduce stress applied to at least one portion (e.g., lower portions) of conductive layer SL, but may increase stress applied to at least one other portion (e.g., upper portions) of conductive layer SL.

According to one or more exemplary embodiments, inorganic layer 803 and organic layer 805 may correspond to one or more of gate insulating layer 611 and interlayer dielectric layer 615. That is, at least one of gate insulating layer 611 and interlayer dielectric layer 615 may extend into pad area PA, and, thereby, be disposed between conductive layer SL and flexible substrate 11. It is also contemplated that at least one of gate insulating layer 611 and/or interlayer dielectric layer 615 may merely correspond to inorganic layer 803. Given that at least one of gate insulating layer 611 and interlayer dielectric layer 615 may be formed as inorganic layer 803, inorganic layer 803 may be patterned in pad area PA to enable organic layer 805 to be disposed in the removed area of inorganic layer 703. When neither of gate insulating layer 611 and interlayer dielectric layer 615 are formed from organic materials, organic layer 805 may be separately formed in the removed area of inorganic layer 803.

In one or more exemplary embodiments, organic layer 805 may interface with conductive layer SL in pad area PA, and, as such, may facilitate stress/strain reduction in pad area PA when pad area PA is deformed. In other words, because organic materials generally have a lower modulus of elasticity than inorganic materials, the presence of organic layer 805 in pad area PA may enable pad area PA to be more easily deformed about bending axis BX. As the force required to bend pad area PA decreases, the amount of stress or strain imposed on conductive layer SL in pad area PA will also decrease. Exemplary embodiments, however, are not limited thereto or thereby. For example, only inorganic layer 803 or only organic layer 805 may extend from display area DA into pad area PA.

To further reduce stress or strain imposed on conductive layer SL in pad area PA when pad area PA is deformed, bending protection layer 807 may be formed on conductive layer SL in pad area PA. In this manner, conductive layer SL may be disposed between bending protection layer 807 and flexible substrate 11. Bending protection layer 807 may be formed of any suitable organic material, such as, an acrylate polymer and/or at least one of the previously mentioned organic materials. The presence of bending protection layer 807 may cause, at least in part, a neutral plane of pad area PA to gravitate towards conductive layer SL when pad area PA is bent about bending axis BX. In addition, bending protection layer 807 may provide further support and external force protection for conductive layer 807. Even still, the relative rigidity of flexible substrate 11 with a relatively larger modulus of elasticity in comparison to the relative elasticity of bending protection layer 807 with a relatively smaller modulus of elasticity may prevent the neutral plane from extending through conductive layer SL, as seen in FIG. 9. As such, conductive layer SL may be held under tension when pad area PA is bent from plane PL, and, for instance, below display area DA. Even though the level of tension may be less than if bending protection layer 807 was omitted, the tension may still cause, at least in part, resistance in conductive layer SL to increase, cracks in surfaces of conductive layer SL to form, and/or conductive layer SL to delaminate from one or more adjacent layers. These defects may reduce the reliability and performance of flexible display panel 10.

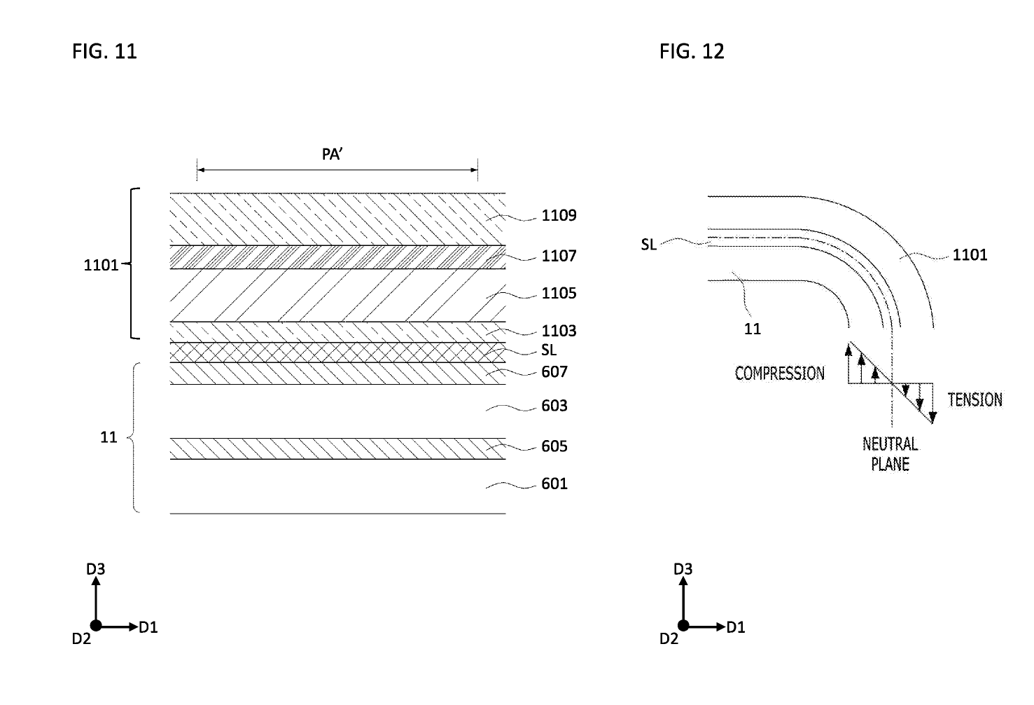

According to one or more exemplary embodiments, conductive layer SL may be symmetrically ordered in a stack of organic and inorganic layers to cause, at least in part, the neutral plane to extend through conductive layer SL. In this manner, when pad area PA is bent, the stress/strain loading on conductive layer SL may be further reduced and may increase reliability and performance of flexible display panel 10. FIGS. 11-15 provide illustrative examples of such symmetrically ordered configurations in pad areas PA′ and PA″.

FIG. 11 is an enlarged view of portion C in a bending portion of the flexible display panel of FIG. 3A, according to one or more exemplary embodiments. FIG. 12 schematically illustrates a neutral plane of the bending portion of the flexible display panel of FIG. 11, according to one or more exemplary embodiments. Various layers of pad portion PA′ are similar to layers described in association with portion A of flexible display panel 10. As such, duplicative descriptions are primarily omitted to avoid obscuring exemplary embodiments

Referring to FIGS. 3A, 5, 6A, 11, and 12, conductive layer SL may be symmetrically ordered in a stack including organic layers and inorganic layers. For instance, an order of organic layers and inorganic layers of flexible substrate 11 may be mirrored about conductive layer SL in stack 1101 disposed on conductive layer SL. In other words, the order of organic layers and inorganic layers in stack 1101 may correspond to a mirrored order of organic layers and inorganic layers in flexible substrate 11. In this manner, conductive layer SL may be disposed between stack 1101 and flexible substrate 11. Conductive layer SL may be formed with the same material and layer configuration of gate electrode 613. That is, conductive layer SL may be formed simultaneously with gate electrode 613. It is contemplated, however, that conductive layer SL may be separately formed from one or more features of display area DA. In this manner, conductive layer SL may be formed with a different material(s) and/or different layer configuration than gate electrode 613. To this end, conductive layer SL may be formed with the same or different material(s) and/or layer configuration as source electrode 621 and drain electrode 623 of thin film transistor TFT.

Dissimilar to conductive layer SL in FIG. 8, conductive layer SL in FIG. 11 may be disposed on flexible substrate 11, e.g., on inorganic layer 607. As such, inorganic layer 1103 is disposed on conductive layer SL, such that conductive layer SL is disposed between inorganic layers 607 and 1103. Given that conductive layer SL is formed on flexible substrate 11, surfaces of conductive layer SL may be substantially planar, unlike as described in association with FIGS. 8-10. It is noted, however, that one or more surfaces of conductive layer SL may be formed to be undulating or at least not planar. Inorganic layer 1103 may correspond to at least one of gate insulating layer 611 and interlayer dielectric layer 615. That is, at least one of gate insulating layer 611 and interlayer dielectric layer 615 may extend from display area DA into pad area PA′ to form inorganic layer 1103. To this end, the modulus of elasticity of inorganic layer 607 may be substantially equivalent to or at least sufficiently matched with the modulus of elasticity of inorganic layer 1103 to further anchor the neutral plane within conductive layer SL.

According to one or more exemplary embodiments, organic layer 1105, inorganic layer 1107, and organic layer 1109 may be sequentially stacked on inorganic layer 1103, such that conductive layer SL is symmetrically ordered between alternating organic and inorganic layers of stack 1101 and alternating organic and inorganic layers of flexible substrate 11. For instance, the order of layers in pad area PA′ may be O-I-O-I-M-I-O-I-O, with “O” representing an organic layer, “I” representing an inorganic layer, and “M” representing conductive layer SL. In this manner, the order of layers disposed above conductive layer SL may mirror the order of layers disposed below conductive layer SL.

In one or more exemplary embodiments, organic layer 1105 may correspond to passivation layer 625. That is, passivation layer 625 may extend from display area DA into pad area PA′ to form organic layer 1105. To this end, organic layer 1109 may correspond to pixel definition layer 630. That is, pixel definition layer 630 may extend from display area DA into pad area PA′ to form organic layer 1109. According to one or more exemplary embodiments, one or more protrusions (not shown) may be formed on (or as part of) an upper surface of pixel definition layer 630 to facilitate reliable manufacture of intermediate layer 631. In this manner, the material forming the protrusions, whether the same as or different from the material forming pixel definition layer 630, may further form a portion of organic layer 1109 in pad area PA′. It is noted that the protrusions may be formed of any suitable organic material, such as one or more of the previously mentioned organic materials.

Inorganic layer 1107 may correspond to pixel electrode 627. That is, inorganic layer 1107 may be formed simultaneously with the formation of pixel electrode 627. As such, the material(s) and layer configuration of pixel electrode 627 may correspond to the material(s) and layer configuration of inorganic layer 1107 in pad area PA′. Inorganic layer 1107 may or may not extend into display area DA. In those instances when pixel electrode 627 includes a multiple layer structure and corresponds to inorganic layer 1107, conductive layer SL may also include a multiple layer structure. The materials of pixel electrode 627 and conductive layer SL may or may not be similar to one another. For instance, pixel electrode 627 may have a multiple layer structure of TiO/Ag/TiO, whereas conductive layer SL may have a multiple layer structure of Ti/Al/Ti. It is also contemplated that the formation of inorganic layer 1107 may be a separate process from the formation of the layers in display area DA. In this manner, inorganic layer 1107 may not correspond to at least one of the layers in display area DA. It is noted, however, that inorganic layer 1107 may be formed of any suitable inorganic material, such as one or more of the aforementioned inorganic materials, e.g., SiOₓ, SiNₓ, etc.

In one or more exemplary embodiments, thicknesses of stack 1101 and flexible substrate 11 may be substantially equivalent to one another. As such, material selection for one or more of organic layers 601, 603, 1105, and 1109 and inorganic layers 605, 607, 1103, and 1107 may be determined such that an effective modulus of elasticity for stack 1101 may be substantially equivalent to an effective modulus of elasticity for flexible substrate 11. It is also contemplated that the relative thicknesses of one or more of organic layers 601, 603, 1105, and 1109 and inorganic layers 605, 607, 1103, and 1107 may be adjusted to account for differences in the effective modulus of elasticity for stack 1101 and the effective modulus of elasticity of flexible substrate 11. In this manner, material selection and/or thicknesses of one or more of organic layers 601, 603, 1105, and 1109 and inorganic layers 605, 607, 1103, 1107 may be adjusted such that a neutral plane of pad area PA′, when pad area PA′ is bent about bending axis BX, extends through conductive layer SL.

According to one or more exemplary embodiments, the configuration of flexible display panel 10 in the bending portion may be characterized by the following:

Mt₁≈Mt₂ Eq. 1

Mt₁=M_{E11}*t₁₁ Eq. 2

Mt₂=M_{E1101}*t₁₁₀₁ Eq. 3

where:

M_{E11}=Effective Modulus of Elasticity of Flexible Substrate 11

M_{E1101}=Effective Modulus of Elasticity of Stack 1101

t₁₁=Aggregate Thickness of Flexible Substrate 11

T₁₁₀₁=Aggregate Thickness of Stack 1101

According to one or more exemplary embodiments, a relative difference between Mt₁ and Mt₂ may be less than 50 percent. To this end, respective thicknesses of organic layers 601, 603, 1105, and 1109 may range from 1 μm to 20 μm, whereas respective thicknesses of inorganic layers 605, 607, 1103, and 1107 may range from 0.5 μm to 5 μm. It is noted, however, that exemplary embodiments are not limited thereto or thereby. In this manner, the amount of stress or strain imposed on conductive layer SL in pad area PA′ may be eliminated in those portions of conductive layer SL through which the neutral plane extends and may be at least reduced in those portions of conductive layer SL spaced apart from the neutral plane, as shown in FIG. 12.

According to one or more exemplary embodiments, material selection and/or thicknesses of one or more of organic layers 601, 603, 1105, and 1109, inorganic layers 605, 607, 1103, 1107, and conductive layer SL may be adjusted so that a larger portion of conductive layer SL is held under compression versus tension, or vice versa. For instance, depending on the material and layer configuration of conductive layer SL, conductive layer SL may be stronger under compression or under tension. As such, by modifying the materials and/or thicknesses of one or more of organic layers 601, 603, 1105, and 1109, inorganic layers 605, 607, 1103, and 1107, and conductive layer SL, the position of the neutral axis relative to conductive layer SL may take advantage of the relative strengths of the materials and layer configuration of conductive layer SL. In this manner, Equation 1 may be modified as follows:

Mt₁=k*Mt₂ Eq. 4

where:

k=Proportionality Constant

For example, assuming conductive layer SL performs better under compression, the position of the neutral plane may be adjusted so that the neutral plane extends through or is relatively close to an interface between conductive layer SL and stack 1101. As such, defects associated with stress or strain at the interface between conductive layer SL and stack 1101 may be reduced (or eliminated), and the relative strengths of conductive layer SL under compression may be taken advantage of in conductive layer SL and at the interface between conductive layer SL and flexible substrate 11.

It is contemplated, however, that the opposite may be true, e.g., the material and layer configuration of conductive layer SL may perform better under tension. As such, material selection and/or thicknesses of one or more of organic layers 601, 603, 1105, and 1109, inorganic layers 605, 607, 1103, and 1107, and conductive layer SL may be selected so that the position of the neutral plane extends through or is relatively close to an interface between conductive layer SL and flexible substrate 11. As such, defects associated with stress or strain at the interface between conductive layer SL and flexible substrate 11 may at least be reduced, and the relative strength of conductive layer SL under tension may be taken advantage of in conductive layer SL and at the interface between conductive layer SL and stack 1101.

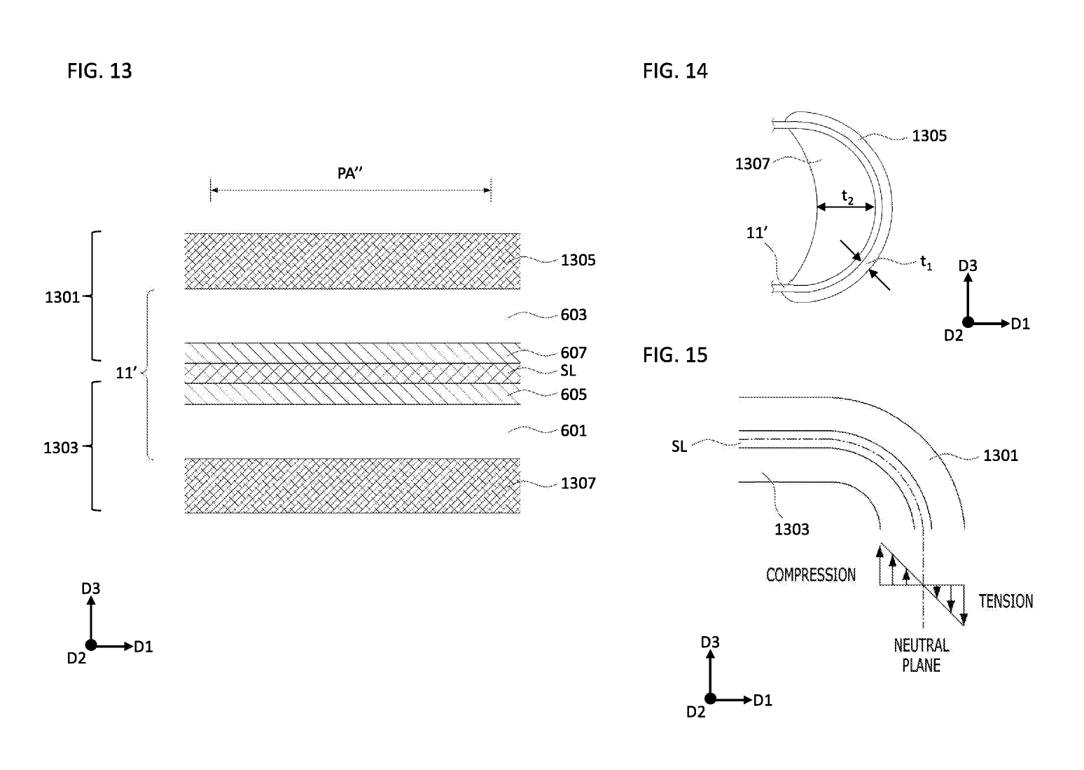

According to one or more exemplary embodiments, conductive layer SL may not only be symmetrically ordered in a stack of organic and inorganic layers to cause, at least in part, the neutral plane to extend through conductive layer SL, but conductive layer SL may be buried in (or be formed as part of) flexible substrate 11′. As such, when pad area PA is bent, the stress and/or strain loading on conductive layer SL may be further reduced and may increase reliability and performance of flexible display panel 10. FIGS. 13-15 provide an illustrative example of conductive layer SL being buried in flexible substrate 11′ in at least pad area PA″.

FIG. 13 is an enlarged view of portion C in a bending portion of the flexible display panel of FIG. 3A, according to one or more exemplary embodiments. FIG. 14 is partial cross-sectional view of a bending portion of the flexible display panel of FIGS. 3B and 13, according to one or more exemplary embodiments. FIG. 15 schematically illustrates a neutral plane of the bending portion of the flexible display panel of FIGS. 13 and 14, according to one or more exemplary embodiments. Various layers of pad portion PA′ are similar to layers described in association with portion A of flexible display panel 10. To this end, the effect on the neutral plane of pad area PA″ may be achieved in a similar fashion as achieved in association with pad area PA′ of FIGS. 11 and 12. As such, duplicative descriptions are primarily omitted to avoid obscuring exemplary embodiments.

Referring to FIGS. 3A, 5, 6A, and 13-15, conductive layer SL may be disposed in or otherwise form a layer of flexible substrate 11′, as described in association FIG. 6C. That is, conductive layer SL may be disposed between inorganic layers 605 and 607 of flexible substrate 11′, and inorganic layers 605 and 607 may be disposed between organic layers 601 and 603 of flexible substrate 11′. Given that conductive layer SL is formed between inorganic layers 605 and 607 of flexible substrate 11′, surfaces of conductive layer SL may be substantially planar, unlike as described in association with FIGS. 8-10. It is noted, however, that one or more surfaces of conductive layer SL may be formed to be undulating or at least not planar. To this end, conductive layer SL may be formed with the same materials and layer configuration as at least one of gate electrode 613, source electrode 621, and drain electrode 623, or may be formed with different materials and/or different layer configuration than one or more of gate electrode 613, source electrode 621, and drain electrode 623.

According to one or more exemplary embodiments, conductive layer SL may be symmetrically ordered in a stack including organic layers and inorganic layers. For instance, an order of organic layers and inorganic layers of first stack 1301 may be mirrored about conductive layer SL in second stack 1303 of organic layers and inorganic layers. In this manner, conductive layer SL is disposed between first stack 1301 and second stack 1303. To this end, the modulus of elasticity and thickness of organic layers 601 and 603 may be equivalent, as may the modulus of elasticity and thickness of inorganic layers 605 and 607. Exemplary embodiments, however, are not limited thereto or thereby.

According to one or more exemplary embodiments, organic layer 1305 may be disposed on organic layer 603, whereas organic layer 1307 may be disposed on organic layer 601. In this manner, the order of layers in pad area PA″ may be O-O-I-M-I-O-O, with “0” representing an organic layer, “I” representing an inorganic layer, and “M” representing conductive layer SL. In this manner, the order of layers disposed above conductive layer SL may mirror the order of layers disposed below conductive layer SL, but the organic layers and inorganic layers of FIGS. 13-15 do not alternate with one another, unlike the organic layers and inorganic layers of FIGS. 11 and 12.

Similar to organic layer 1109 of FIG. 11, organic layer 1305 may correspond to at least one of passivation layer 625 and pixel definition layer 630. That is, at least one of passivation layer 625 and pixel definition layer 630 may extend from display area DA into pad area PA″ to form organic layer 1305. To this end, one or more protrusions (not shown) may be formed on (or as part of) an upper surface of pixel definition layer 630 to facilitate reliable manufacture of intermediate layer 631. As such, the material forming the protrusions, whether the same as or different from the material forming pixel definition layer 630, may further form a portion of organic layer 1305 in pad area PA″. It is noted that the protrusions may be formed of any suitable organic material, such as one or more of the previously mentioned organic materials. It is also contemplated that organic layer 1305 may not correspond to a layer of display area DA. In this manner, organic layer 1305 may be formed separately from the structures formed in display area DA of flexible display panel 10. For instance, organic layer 1305 may be formed of an acrylate polymer.

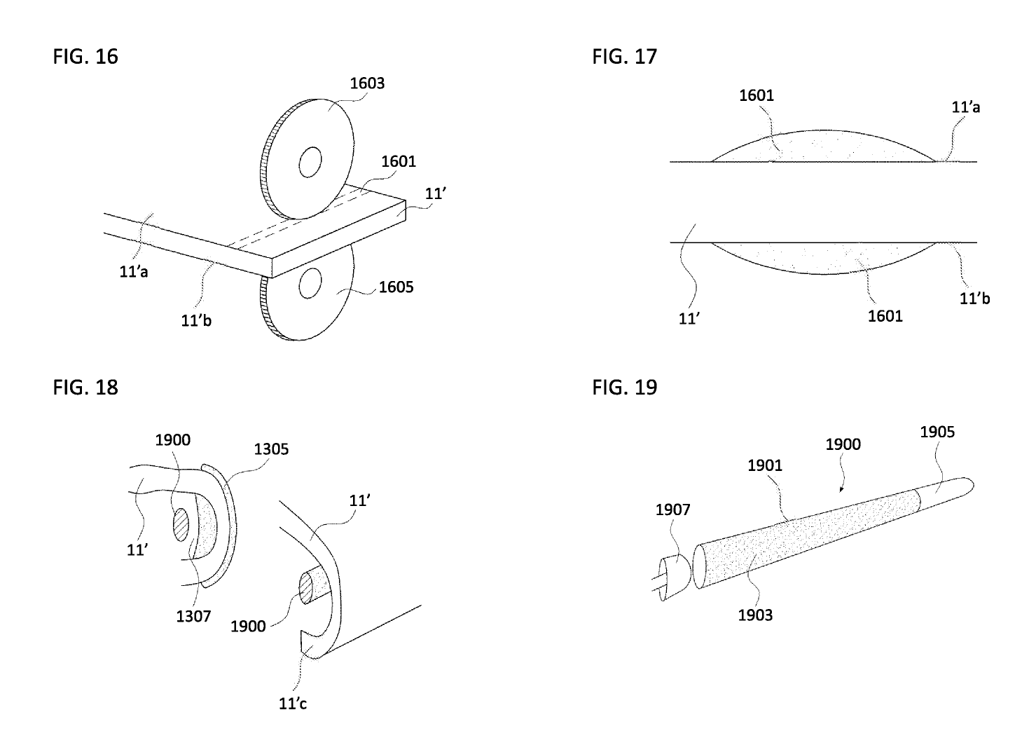

In one or more exemplary embodiments, organic layer 1307 may be formed separately from the structures formed in display area DA of flexible display panel 10. Organic layer 1307 may be formed of any suitable organic material, such as, an acrylate polymer and/or at least one of the previously mentioned organic materials. In one or more exemplary embodiments, organic layer 1305 and organic layer 1307 may be simultaneously formed, as is described in more detail in association with FIGS. 16-19. It is also noted that organic layers 1305 and 1307 may include multiple successively formed layers of a same or different organic material. In one or more exemplary embodiments, thicknesses of organic layers 1305 and 1307 may be different from one another. For instance, a thickness t₁ of organic layer 1305 may be smaller than a thickness t₂ of organic layer 1307. To this end, the modulus of elasticity of organic layer 1305 may be the same as or different from the modulus of elasticity of organic layer 1307.

According to one or more exemplary embodiments, thicknesses of first stack 1301 and second stack 1305 may be substantially equivalent to one another. As such, material selection for one or more of organic layers 601, 603, 1305, and 1307 and inorganic layers 605 and 607 may be determined such that an effective modulus of elasticity for first stack 1301 may be substantially equivalent to an effective modulus of elasticity for second stack 1303. It is also contemplated that the relative thicknesses of one or more of organic layers 601, 603, 1305, and 1307 and inorganic layers 605 and 607 may be adjusted to account for differences in the effective modulus of elasticity for first stack 1301 and the effective modulus of elasticity of second stack 1303. In this manner, material selection and/or thicknesses of one or more of organic layers 601, 603, 1305, and 1307 and inorganic layers 605 and 607 may be adjusted such that a neutral plane of pad area PA″, when pad area PA″ is bent about bending axis BX, extends through conductive layer SL.

According to one or more exemplary embodiments, the configuration of flexible display panel 10 in the bending portion may be characterized by the following:

Mt₃≈Mt₄ Eq. 5

Mt₃=M_{E1301}*t₁₃₀₁ Eq. 6

Mt₄=M_{E1303}*t₁₃₀₃ Eq. 7

where:

M_{E1301}=Effective Modulus of Elasticity of Stack 1301

M_{E1303}=Effective Modulus of Elasticity of Stack 1303

t₁₃₀₁=Aggregate Thickness of Stack 1301

T₁₃₀₃=Aggregate Thickness of Stack 1303

According to one or more exemplary embodiments, a relative difference between Mt₃ and Mt₄ may be less than 50 percent. To this end, respective thicknesses of organic layers 601, 603, 1305, and 1307 may range from 1 μm to 20 μm, whereas respective thicknesses of inorganic layers 605 and 607 may range from 0.5 μm to 5 μm. It is noted, however, that exemplary embodiments are not limited thereto or thereby. In this manner, the amount of stress or strain imposed on conductive layer SL in pad area PA″ may be eliminated in those portions of conductive layer SL through which the neutral plane extends and may be at least reduced in those portions of conductive layer SL spaced apart from the neutral plane, as seen in FIG. 15.

According to one or more exemplary embodiments, material selection and/or thicknesses of one or more of organic layers 601, 603, 1305, and 1307, inorganic layers 605 and 607, and conductive layer SL may be adjusted so that a larger portion of conductive layer SL is held under compression versus tension, or vice versa. For instance, depending on the material and layer configuration of conductive layer SL, conductive layer SL may be stronger under compression or under tension. As such, by modifying the materials and/or thicknesses of one or more of organic layers 601, 603, 1305, and 1307, inorganic layers 605 and 607, and conductive layer SL, the position of the neutral plane relative to conductive layer SL may take advantage of the relative strengths of the materials and layer configuration of conductive layer SL. Since a similar effect was previously described in association with FIGS. 11 and 12, a duplicative description has been omitted to avoid obscuring exemplary embodiments. It is noted, however, that Equation 5 may be modified as follows:

Mt₃=k*Mt₄ Eq. 8

where:

k=Proportionality Constant

FIGS. 16 and 17 schematically illustrate a process of depositing organic material on surfaces of a flexible substrate in a bending portion of a flexible display device, according to one or more exemplary embodiments. FIG. 18 schematically illustrates a process of curing the deposited organic material of FIG. 17, according to one or more exemplary embodiments. FIG. 19 is a perspective view of a curing apparatus, according to one or more exemplary embodiments.

Referring to FIG. 16, organic material 1601 may be simultaneously formed in pad area PA″ on opposing surfaces 11′a and 11′b of flexible substrate 11′ via, for instance, rollers 1603 and 1605. It is contemplated, however, that any other suitable manner of depositing organic material on opposing surfaces 11′a and 11′b may be utilized in association with exemplary embodiments. In this manner, organic material 1601 may be deposited on flexible substrate 11′ in pad area PA″ in a viscous, liquid state, as seen in FIG. 17. After pad area PA″ is bent, the organic material 1601 may be cured to form organic layers 1305 and 1307. For instance, ultraviolet light may be utilized to cure organic material 1601 on surfaces 11′a and 11′b of flexible substrate 11′. Given that the bend radius of flexible substrate 11′ is relatively small, it may be difficult to cure organic material 1601 on surface 11′b. As such, curing apparatus 1900 may be utilized to radiate ultraviolet light toward organic material 1601.

Adverting to FIG. 19, curing apparatus 1900 may include fiber optic cable (or lance) 1901 with light scattering features (e.g., dents, particles, etc.) 1903 configured to redirect light propagating in a longitudinal direction of fiber optic cable 1901 to a radial direction of fiber optic cable 1901. When fiber optic cable 1901 is not sufficiently rigid to be fed between opposing portions of flexible substrate 11′ when pad area PA″ is bent about bending axis BX, curing apparatus 1900 may include rigid needle point 1905 to facilitate a “threading” process that disposes curing apparatus 1900 near organic material 1601, as seen in FIG. 18.

In one or more exemplary embodiments, rigid needle point 1905 may be magnetic to further facilitate the “threading” process. For instance, rigid needle point 1905 may be disposed at first lateral side 11′c of flexible substrate 11′ and a magnet (not shown) may be displaced above and along, for instance, surface 11 ‘a to “thread” curing apparatus 1900 between and along the opposing portions of flexible substrate 11’. To this end, an ultraviolet light source 1907 may emit ultraviolet light for propagation along fiber optic cable 1901 and towards organic material 1601 via light scattering features 1903. In this manner, scattered ultraviolet light may cause the deposited organic material 1601 on surface 11′b to be cured. The process of FIGS. 16-18 may be repeated multiple times to form multiple layers, and, thereby, build-up organic layers 1305 and 1307. Although organic layer 1307 is shown with a concave outer surface, it is noted that other surface configurations may be formed, such as convex outer surfaces.

Although certain exemplary embodiments and implementations have been described herein, other embodiments and modifications will be apparent from this description. Accordingly, the inventive concept is not limited to such embodiments, but rather to the broader scope of the presented claims and various obvious modifications and equivalent arrangements.

What is claimed is:

1. An apparatus comprising:
a flexible substrate comprising:
a first area extending along a plane; and
a second area extending from the first area, the second area being bent away from the plane;
an electrode overlapping the first area; and
a signal line disposed in association with the first area and the second area, the signal line being electrically connected to the electrode,
wherein a neutral plane of the second area extends in the signal line.

2. The apparatus of claim 1, wherein, in association with the second area, the signal line is symmetrically ordered in a stack of organic layers and inorganic layers.

3. The apparatus of claim 2, wherein:
the stack comprises the signal line disposed between a pair of inorganic layers; and
a combined thickness of the signal line and the pair of inorganic layers is greater than or equal to 100 nm and less than or equal to 900 nm.

4. The apparatus of claim 2, wherein the stack comprises:
a first organic layer;
a first inorganic layer disposed on the first organic layer;
a second organic layer disposed on the first inorganic layer;
a second inorganic layer disposed on the second organic layer;
the signal line disposed on the second inorganic layer;
a third inorganic layer disposed on the signal line;
a third organic layer disposed on the third inorganic layer;
a fourth inorganic layer disposed on the third organic layer; and
a fourth organic layer disposed on the fourth inorganic layer.

5. The apparatus of claim 4, wherein:
the flexible substrate is formed comprising the first organic layer, the first inorganic layer, the second organic layer, and the second inorganic layer; and
the signal line is disposed on the flexible substrate.

6. The apparatus of claim 5, wherein:
the electrode forms a portion of a thin film transistor; and
the third inorganic layer extends between the electrode and the flexible substrate.

7. The apparatus of claim 5, wherein:
a pixel electrode is disposed on the third organic layer; and
the electrode forms a portion of a thin film transistor, the pixel electrode being connected to the electrode through a contact hole formed in the third organic layer.

8. The apparatus of claim 7, wherein:
the fourth organic layer comprises a patterned region overlapping the pixel electrode; and
an organic layer is disposed in the patterned region, the organic layer being configured to emit light.

9. The apparatus of claim 5, wherein:
the signal line comprises a first multilayer structure; and
the fourth inorganic layer comprises a second multilayer structure.

10. The apparatus of claim 9, wherein:
the first multilayer structure comprises a first metal layer stacked between second metal layers; and
the second multilayer structure comprises a third metal layer stacked between metal oxide layers.

11. The apparatus of claim 10, wherein:
the first metal layer comprises aluminum;
the second metal layers comprise titanium;
the third metal layer comprises silver; and
the metal oxide layers comprise indium tin oxide.

12. The apparatus of claim 10, further comprising:
a pixel electrode overlapping the first area,
wherein the pixel electrode comprises the second multilayer structure.

13. The apparatus of claim 4, wherein the third inorganic layer, the third organic layer, the fourth inorganic layer, and the fourth organic layer overlap the first area and the second area.

14. The apparatus of claim 4, wherein the first organic layer and the second organic layer comprise polyimide.

15. The apparatus of claim 2, wherein the stack comprises:
a first organic layer;
a second organic layer disposed on the first organic layer;
a first inorganic layer disposed on the second organic layer;
the signal line disposed on the first inorganic layer;
a second inorganic layer disposed on the signal line;
a third organic layer disposed on the second inorganic layer; and
a fourth organic layer disposed on the third organic layer.

16. The apparatus of claim 15, wherein the flexible substrate is formed comprising the second organic layer, the first inorganic layer, the signal line, the second inorganic layer, and the third organic layer.

17. The apparatus of claim 16, wherein the second organic layer, the third organic layer, and the fourth organic layer comprise polyimide.

18. The apparatus of claim 17, wherein coefficients of thermal expansion of the fourth organic layer and the second organic layer are different from one another.

19. The apparatus of claim 15, further comprising:
a pixel electrode overlapping the first area,
wherein:
the electrode forms a portion of a thin film transistor;
the fourth organic layer overlaps the first area and the second area; and
the pixel electrode is electrically connected to the electrode of the thin film transistor through a contact hole formed in the fourth organic layer.

20. The apparatus of claim 15, further comprising:
a pixel electrode overlapping the first area,
wherein:
the fourth organic layer overlaps the first area and the second area;
the fourth organic layer comprises a patterned region overlapping the pixel electrode; and
an organic layer is disposed in the patterned region, the organic layer being configured to emit light.

21. The apparatus of claim 15, wherein the first organic layer is thicker than the fourth organic layer.

22. The apparatus of claim 21, wherein the first organic layer and the fourth organic layer comprise an acrylate polymer.

23. The apparatus of claim 1, wherein:
the electrode forms a portion of a thin film transistor; and
a material of the signal line corresponds with a material of the electrode.

24. The apparatus of claim 1, wherein:
the first area overlaps an active area of the apparatus; and
the second area overlaps an inactive area of the apparatus.

25. The apparatus of claim 24, wherein:
the active area comprises at least one of a display area and a sensing area; and
the inactive area comprises at least one of a non-display area and a non-sensing area.

26. An apparatus comprising:
a flexible substrate comprising:
a first area extending along a plane; and
a second area extending from the first area, the second area being bent away from the plane;
a thin film transistor overlapping the first area; and
a signal line disposed in association with the first area and the second area, the signal line being electrically connected to the thin film transistor,
wherein, in association with the second area, the signal line is disposed between a first inorganic layer and a second inorganic layer, and
wherein, in association with the first area, the second inorganic layer is disposed between an electrode of the thin film transistor and the first inorganic layer.

27. The apparatus of claim 26, wherein a neutral plane of the second area extends in the signal line.

28. An apparatus comprising:
a flexible substrate; and
an electrode disposed on a plane of a first portion of the flexible substrate, a second portion of the flexible substrate being bent away from the plane,
wherein a signal line is embedded in the flexible substrate between a pair of inorganic layers of the flexible substrate, the signal line being electrically connected to the electrode, and
wherein the signal line extends from the second portion into the first portion.

29. The apparatus of claim 28, wherein the pair of inorganic layers are stacked between a first organic layer of the flexible substrate and a second organic layer of the flexible substrate.

30. The apparatus of claim 28, wherein a neutral plane of the second portion extends in the signal line.
